(19) United States
(12) Patent Application Publication
(10) Pub. No.: US 2026/0032906 A1
(43) Pub. Date: Jan. 29, 2026

(54) THREE-DIMENSIONAL MEMORY DEVICES AND METHODS FOR FORMING THE SAME

(71) Applicant: YANGTZE MEMORY TECHNOLOGIES CO., LTD., Wuhan (CN)

(72) Inventors: Kuan Dong, Wuhan (CN); Meng Xiao, Wuhan (CN); Gang Zhang, Wuhan (CN); Hao Zhang, Wuhan (CN); Zongliang Huo, Wuhan (CN)

(21) Appl. No.: 18/799,499

(22) Filed: Aug. 9, 2024

(30) Foreign Application Priority Data
Jul. 23, 2024 (CN) 202410994504.3

(51) Int. Cl. H10B 43/27

(52) U.S. Cl. CPC H10B 43/27

(57) ABSTRACT

In certain aspects, a memory device includes a stack structure, a conductive structure, and a contact structure. The stack structure includes alternating first layers and first dielectric layers. The first layers in a first portion of the stack structure include second dielectric layers, and the first layers in a second portion adjacent to the first portion of the stack structure include conductive layers. The conductive structure is in a same layer as a conductive layer from the conductive layers and connected to the conductive layer. At least one part of the conductive structure is in the first portion of the stack structure. The contact structure extends through and is connected to the at least one part of the conductive structure in the first portion of the stack structure.

### CROSS-REFERENCE TO RELATED APPLICATIONS

This application claims the benefit of priority to Chinese Application No. 202410994504.3, filed on Jul. 23, 2024, which is incorporated herein by reference in its entirety.

### BACKGROUND

The present disclosure relates to three-dimensional (3D) memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A 3D memory architecture can address the density limitation in planar memory cells. The 3D memory architecture includes a memory array and peripheral devices for controlling signals to and from the memory array.

### SUMMARY

In one aspect, a memory device includes a stack structure, a conductive structure, and a contact structure. The stack structure includes alternating first layers and first dielectric layers. The first layers in a first portion of the stack structure include second dielectric layers, and the first layers in a second portion adjacent to the first portion of the stack structure include conductive layers. The conductive structure is in a same layer as a conductive layer from the conductive layers and connected to the conductive layer. At least one part of the conductive structure is in the first portion of the stack structure. The contact structure extends through and is connected to the at least one part of the conductive structure in the first portion of the stack structure.

In some implementations, the memory device further includes an isolation structure extending through the stack structure. The isolation structure is located between the first portion and the second portion of the stack structure to isolate the first portion from the second portion.

In some implementations, the isolation structure surrounds the first portion of the stack structure, and the conductive structure extends through the isolation structure to connect to the conductive layer in the second portion of the stack structure.

In some implementations, the isolation structure includes: one or more first isolation members extending into the stack structure through the conductive structure; and second isolation members extending into the stack structure outside the conductive structure. In a cross-section of the isolation structure in a lateral plane perpendicular to an extending direction of the contact structure, the one or more first isolation members are surrounded by and separated by the conductive structure, and the second isolation members are connected to one another to isolate the conductive layer from one of the second dielectric layers in the same layer as the conductive layer.

In some implementations, in the cross-section of the isolation structure in the lateral plane, the second isolation members are connected to one another to form an isolation wall, and a sidewall of the isolation wall includes a plurality of arc surfaces connected to one another.

In some implementations, the conductive structure has a ring shape.

In some implementations, the memory device further includes a dielectric structure extending into the first portion of the stack structure in a same direction as the contact structure. The dielectric structure extends through the at least one part of the conductive structure, and a bottom portion of the dielectric structure is surrounded by the at least one part of the conductive structure.

In some implementations, the dielectric structure has a pillar shape.

In some implementations, the dielectric structure includes a dielectric material different from that of the second dielectric layers.

In some implementations, the contact structure extends through the at least one part of the conductive structure outside the dielectric structure.

In some implementations, the memory device further includes: a channel structure extending through the second portion of the stack structure in a same direction as the contact structure; and a slit structure extending through the second portion of the stack structure in the same direction as the contact structure.

In some implementations, the channel structure includes a plurality of channel segments. The isolation structure includes isolation members each of which includes a plurality of isolation segments corresponding to the plurality of channel segments, respectively. The contact structure includes a plurality of contact segments corresponding to the plurality of channel segments, respectively. The slit structure includes slit members each of which includes a plurality of slit segments corresponding to the plurality of channel segments, respectively.

In some implementations, the plurality of channel segments include a first channel segment and a second channel segment on the first channel segment. A first end of the first channel segment is away from the second channel segment, a second end of the first channel segment is connected to a first end of the second channel segment, and a second end of the second channel segment is away from the first channel segment. In a lateral direction perpendicular to an extending direction of the contact structure, a size of the first end of the first channel segment is smaller than a size of the second end of the first channel segment, and a size of the first end of the second channel segment is smaller than the size of the second end of the first channel segment and a size of the second end of the second channel segment.

In some implementations, a channel-structure shoulder is formed at a location where the second end of the first channel segment is connected to the first end of the second channel segment.

In some implementations, the slit structure includes a plurality of first slit members and a plurality of second slit members extending through the second portion of the stack structure. In a cross-section of the slit structure in a lateral plane perpendicular to an extending direction of the contact structure, the plurality of first slit members are connected to one another, and the plurality of second slit members are also connected to one another.

In some implementations, the dielectric structure is located between the plurality of first slit members and the plurality of second slit members. A first distance between the dielectric structure and the plurality of first slit members is smaller than a second distance between the dielectric structure and the plurality of second slit members. The contact structure is located between the dielectric structure and the plurality of second slit members.

In some implementations, the memory device further includes a plurality of contact structures extending in the first portion of the stack structure. The plurality of contact structures include the contact structure, and are arranged in a staggered manner. The memory device further includes a plurality of conductive structures having a one-to-one correspondence to the plurality of contact structures. The plurality of conductive structures include the conductive structure.

In another aspect, a method for forming a memory device is disclosed. The method includes forming a stack structure including alternating first dielectric layers and second dielectric layers. The stack structure includes a first portion and a second portion adjacent to the first portion. The method further includes replacing parts of the second dielectric layers in the second portion of the stack structure with conductive layers, and forming a conductive structure that is in a same layer as a conductive layer from the conductive layers and connected to the conductive layer. At least one part of the conductive structure is in the first portion of the stack structure. The method further includes forming a contact structure that extends through and connects to the at least one part of the conductive structure in the first portion of the stack structure.

In some implementations, the method further includes forming an isolation structure extending through the stack structure. The isolation structure is located between the first portion and the second portion of the stack structure to isolate the first portion from the second portion.

In some implementations, the isolation structure surrounds the first portion of the stack structure, and the conductive structure extends through the isolation structure to connect to the conductive layer in the second portion of the stack structure.

In some implementations, the isolation structure includes: one or more first isolation members extending into the stack structure through the conductive structure; and second isolation members extending into the stack structure outside the conductive structure. In a cross-section of the isolation structure in a lateral plane perpendicular to an extending direction of the contact structure, the one or more first isolation members are surrounded by and separated by the conductive structure, and the second isolation members are connected to one another to isolate the conductive layer from a remainder part of a second dielectric layer from the second dielectric layers. The remainder part of the second dielectric layer is in the first portion of the stack structure and in the same layer as the conductive layer.

In some implementations, the method further includes forming a dielectric structure extending into the first portion of the stack structure in a same direction as the contact structure. The dielectric structure extends through the at least one part of the conductive structure, and a bottom portion of the dielectric structure is surrounded by the at least one part of the conductive structure.

In some implementations, the dielectric structure has a pillar shape.

In some implementations, forming the contact structure includes forming the contact structure extending through the at least one part of the conductive structure outside the dielectric structure.

In some implementations, the method further includes: forming a channel structure extending through the second portion of the stack structure in a same direction as the contact structure; and forming a slit structure extending through the second portion of the stack structure in the same direction as the contact structure.

In some implementations, the method further includes: forming a channel hole and a plurality of slit holes in the second portion of the stack structure, a plurality of isolation holes between the first portion and the second portion of the stack structure, and a contact hole in the first portion of the stack structure; and filling the channel hole, the plurality of slit holes, the plurality of isolation holes, and the contact hole with a first sacrificial material.

In some implementations, forming the channel structure includes: removing the first sacrificial material filled in the channel hole; and forming the channel structure in the channel hole.

In some implementations, forming the conductive structure includes: forming a dielectric opening in the first portion of the stack structure to expose a second dielectric layer under the dielectric opening, where the second dielectric layer is in the same layer as the conductive layer; removing a portion of the second dielectric layer through the dielectric opening to form a lateral opening in the second dielectric layer, where the lateral opening extends laterally from the first portion into the second portion of the stack structure; filling the lateral opening with a second sacrificial material; and forming a sacrificial structure including the second sacrificial material filled in the lateral opening by removing a portion of the second sacrificial material filled below the dielectric opening, where the sacrificial structure also extends laterally from the first portion into the second portion of the stack structure.

In some implementations, forming the dielectric structure includes filling the dielectric opening, as well as an opening derived by removing the portion of the second sacrificial material filled below the dielectric opening, with a dielectric material to form the dielectric structure. The sacrificial structure surrounds the bottom portion of the dielectric structure.

In some implementations, forming the isolation structure includes: removing the first sacrificial material filled in the plurality of isolation holes; and forming a plurality of isolation members in the plurality of isolation holes.

In some implementations, the plurality of isolation holes include one or more first isolation holes extending through the conductive structure and second isolation holes extending outside the conductive structure. Forming the plurality of isolation members in the plurality of isolation holes includes: forming one or more first isolation members in the one or more first isolation holes; and forming second isolation members in the second isolation holes.

In some implementations, forming the second isolation members in the second isolation holes includes forming extended isolation holes by: for each second isolation hole, forming isolation recesses in the second dielectric layers through the second isolation hole, where the isolation recesses and the second isolation hole form a corresponding extended isolation hole. Forming the second isolation members in the second isolation holes further includes forming the second isolation members in the extended isolation holes. In a cross-section of the isolation structure in a lateral plane perpendicular to an extending direction of the contact structure, the second isolation members are connected to one another to form an isolation wall, and a sidewall of the isolation wall includes a plurality of arc surfaces connected to one another.

In some implementations, replacing the parts of the second dielectric layers in the second portion of the stack structure with the conductive layers includes: removing the first sacrificial material filled in the plurality of slit holes; and removing the parts of the second dielectric layers in the second portion of the stack structure through the plurality of slit holes to form a plurality of lateral recesses.

In some implementations, forming the conductive structure further includes: removing the sacrificial structure through a lateral recess to form a sacrificial opening, where the lateral recess is one of the plurality of lateral recesses in the same layer as the conductive layer; and filling the sacrificial opening with a conductive material to form the conductive structure.

In some implementations, replacing the parts of the second dielectric layers in the second portion of the stack structure with the conductive layers further includes filling the plurality of lateral recesses with the conductive material to form the conductive layers.

In some implementations, forming the slit structure includes: forming a plurality of first slit members in a first subset of the plurality of slit holes; and forming a plurality of second slit members in a second subset of the plurality of slit holes. In a cross-section of the slit structure in a lateral plane perpendicular to an extending direction of the contact structure, the plurality of first slit members are connected to one another, and the plurality of second slit members are also connected to one another.

In some implementations, the dielectric structure is located between the plurality of first slit members and the plurality of second slit members. A first distance between the dielectric structure and the plurality of first slit members is smaller than a second distance between the dielectric structure and the plurality of second slit members. The contact structure is located between the dielectric structure and the plurality of second slit members.

In some implementations, forming the contact structure further includes: removing the first sacrificial material filled in the contact hole; and forming the contact structure in the contact hole.

In some implementations, the stack structure includes: a first stack segment including a first subset of the alternating first and second dielectric layers; and a second stack segment including a second subset of the alternating first and second dielectric layers.

In some implementations, forming the channel hole, the plurality of slit holes, the plurality of isolation holes, and the contact hole includes: forming a first channel opening, a plurality of first isolation openings, a plurality of first slit openings, and a first contact opening in the first stack segment; forming a second channel opening, a plurality of second isolation openings, a plurality of second slit openings, and a second contact opening in the second stack segment; and combining the first stack segment with the second stack segment to form the stack structure in which the channel hole, the plurality of isolation holes, the plurality of slit holes, and the contact hole are formed. The channel hole includes the first and second channel openings. The plurality of isolation holes include the plurality of first isolation openings and the plurality of second isolation openings, respectively. The plurality of slit holes include the plurality of first slit openings and the plurality of second slit openings, respectively. The contact hole includes the first and second contact openings.

In some implementations, the channel structure includes a first channel segment formed in the first channel opening and a second channel segment formed in the second channel opening. The isolation structure includes first isolation segments formed in the plurality of first isolation openings, respectively, and second isolation segments formed in the plurality of second isolation openings, respectively. The contact structure includes a first contact segment formed in the first contact opening and a second contact segment formed in the second contact opening. The slit structure includes first slit segments formed in the plurality of first slit openings, respectively, and second slit segments formed in the plurality of second slit openings, respectively.

In some implementations, a first end of the first channel segment is away from the second channel segment, a second end of the first channel segment is connected to a first end of the second channel segment, and a second end of the second channel segment is away from the first channel segment. In a lateral direction perpendicular to an extending direction of the contact structure, a size of the first end of the first channel segment is smaller than a size of the second end of the first channel segment, and a size of the first end of the second channel segment is smaller than the size of the second end of the first channel segment and a size of the second end of the second channel segment.

In some implementations, a channel-structure shoulder is formed at a location where the second end of the first channel segment is connected to the first end of the second channel segment.

In still another aspect, a memory device includes a stack structure, a conductive structure, and an isolation structure. The stack structure includes alternating first layers and first dielectric layers. The first layers in a first portion of the stack structure include second dielectric layers, and the first layers in a second portion adjacent to the first portion of the stack structure include conductive layers. The conductive structure is in a same layer as a conductive layer from the conductive layers and connected to the conductive layer. At least one part of the conductive structure is in the first portion of the stack structure. The isolation structure extends through the stack structure and surrounds the first portion of the stack structure.

In some implementations, the memory device further includes a contact structure extending through and connected to the at least one part of the conductive structure in the first portion of the stack structure.

In some implementations, the conductive structure extends through the isolation structure to connect to the conductive layer in the second portion of the stack structure.

In some implementations, the isolation structure includes: one or more first isolation members extending into the stack structure through the conductive structure; and second isolation members extending into the stack structure outside the conductive structure. In a cross-section of the isolation structure in a lateral plane perpendicular to an extending direction of the contact structure, the one or more first isolation members are surrounded by and separated by the conductive structure, and the second isolation members are connected to one another to isolate the conductive layer from one of the second dielectric layers in the same layer as the conductive layer.

In some implementations, in the cross-section of the isolation structure in the lateral plane, the second isolation members are connected to one another to form an isolation wall, and a sidewall of the isolation wall includes a plurality of arc surfaces connected to one another.

In some implementations, the memory device further includes a dielectric structure extending into the first portion of the stack structure in a same direction as the contact structure. The dielectric structure extends through the at least one part of the conductive structure, and a bottom portion of the dielectric structure is surrounded by the at least one part of the conductive structure.

In some implementations, the contact structure extends through the at least one part of the conductive structure outside the dielectric structure.

In some implementations, the memory device further includes: a channel structure extending through the second portion of the stack structure in a same direction as the contact structure; and a slit structure extending through the second portion of the stack structure in the same direction as the contact structure.

In some implementations, the channel structure includes a plurality of channel segments. The isolation structure includes isolation members each of which includes a plurality of isolation segments corresponding to the plurality of channel segments, respectively. The contact structure includes a plurality of contact segments corresponding to the plurality of channel segments, respectively. The slit structure includes slit members each of which includes a plurality of slit segments corresponding to the plurality of channel segments, respectively.

In some implementations, the plurality of channel segments include a first channel segment and a second channel segment. A first end of the first channel segment is away from the second channel segment, a second end of the first channel segment is connected to a first end of the second channel segment, and a second end of the second channel segment is away from the first channel segment. In a lateral direction perpendicular to an extending direction of the contact structure, a size of the first end of the first channel segment is smaller than a size of the second end of the first channel segment, and a size of the first end of the second channel segment is smaller than the size of the second end of the first channel segment and a size of the second end of the second channel segment.

In some implementations, a channel-structure shoulder is formed at a location where the second end of the first channel segment is connected to the first end of the second channel segment.

In some implementations, the slit structure includes a plurality of first slit members and a plurality of second slit members extending through the second portion of the stack structure. In a cross-section of the slit structure in a lateral plane perpendicular to an extending direction of the contact structure, the plurality of first slit members are connected to one another, and the plurality of second slit members are also connected to one another.

In some implementations, the dielectric structure is located between the plurality of first slit members and the plurality of second slit members. A first distance between the dielectric structure and the plurality of first slit members is smaller than a second distance between the dielectric structure and the plurality of second slit members. The contact structure is located between the dielectric structure and the plurality of second slit members.

In some implementations, the memory device further includes a plurality of contact structures extending in the first portion of the stack structure. The plurality of contact structures include the contact structure, and are arranged in a staggered manner. The memory device further includes a plurality of conductive structures having a one-to-one correspondence to the plurality of contact structures. The plurality of conductive structures include the conductive structure.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a cross-sectional side view of a 3D memory device having a staircase structure, according to some examples of the present disclosure.

FIG. 2A illustrates a plan view of a 3D memory device having contact structures, according to some aspects of the present disclosure.

FIG. 2B illustrates a cross-sectional side view of the 3D memory device of FIG. 2A, according to some aspects of the present disclosure.

FIG. 2C illustrates a cross-sectional view of the 3D memory device of FIG. 2A, according to some aspects of the present disclosure.

FIG. 2D illustrates another cross-sectional side view of the 3D memory device of FIG. 2A, according to some aspects of the present disclosure.

FIGS. 3A-3Y and 4A-4F illustrate a fabrication process for forming a 3D memory device having contact structures, according to some aspects of the present disclosure.

FIG. 5 is a flowchart of a method for forming a 3D memory device having contact structures, according to some aspects of the present disclosure.

FIG. 6 illustrates a block diagram of an exemplary system having a 3D memory device, according to some aspects of the present disclosure.

FIG. 7A illustrates a diagram of an exemplary memory card having a 3D memory device, according to some aspects of the present disclosure.

FIG. 7B illustrates a diagram of an exemplary solid-state drive (SSD) having a 3D memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which lateral contact members and/or vertical contacts are formed) and one or more dielectric layers.

In some 3D memory devices, such as 3D NAND memory devices, memory cells for storing data are vertically stacked through a stack structure (e.g., a memory stack) in vertical channel structures. In some implementations, 3D memory devices may include staircase structures formed on one or more sides (edges), or at the center, of the stacked storage structure for purposes such as word line pick-up/fan-out using word line contacts landed onto different steps/levels of the staircase structure. In some implementations, the word line pick-up/fan-out functions can be achieved without using the staircase structures and word line contacts, so that the manufacturing cost can be reduced, and the fabrication process can be simplified. For example, the two structures-staircase structure and word line contact, as well as their separate processes, can be merged into a single contact structure (e.g., a word line pick-up structure) in one process, thereby reducing the manufacturing cost and simplifying the process.

With the demand for further cost reduction and capacity enhancement, the number of storage layers in the memory device is also increased. However, as the number of storage layers increases, an area occupied by the contact structures is also increased, and it becomes more and more difficult to etch contact holes in a stack structure for forming the contact structures therein. The manufacturing cost of the memory device is increased. Therefore, it is a challenging task to increase the number of storage layers in the memory device while reducing the manufacturing cost at the same time.

On the other hand, because a depth of a channel etching (e.g., etching alternating silicon oxide layers and silicon nitride layers in the stack structure) cannot be more than a thickness of 12 μm each time, each channel structure may be formed in the memory device by stacking a plurality of channel segments together. An area occupied by the contact structures is expanded, causing an area occupied by the channel structures to be reduced. For example, etching a contact hole with a large depth into the stack structure can be difficult. A critical dimension (CD) of a contact structure formed in the contact hole thereof can be large. Thus, an area occupied by contact structures with large CDs can be large, resulting in a reduction in a storage density of the memory device.

To address one or more of the aforementioned issues, the present disclosure introduces a solution which can simplify the fabrication process of a memory device and reduce the manufacturing cost of the memory device. Specifically, in the solution disclosed herein, contact holes in which contact structures are formed can be formed at the same time as channel holes in which channel structures are formed. For example, the stack structure can be formed by a plurality of stack segments, where a plurality of channel openings and a plurality of contact openings are formed in each stack segment. When the plurality of stack segments are combined together (e.g., stacked together or bonded together) to form the stack structure, channel openings in the different stack segments are combined to form respective channel holes, and contact openings in the different stack segments are also combined to form respective contact holes. The plurality of stack segments can be formed separately in any order, which is not limited herein. Thus, the process of forming the contact holes, as well as the process of forming contact structures in the contact holes, can be simplified, and an area occupied by the contact structures can be reduced. As a result, the manufacturing cost of the memory device can be reduced. The contact structures formed thereof may extend through the entire stack structure, and may be referred to as through-type contact structures.

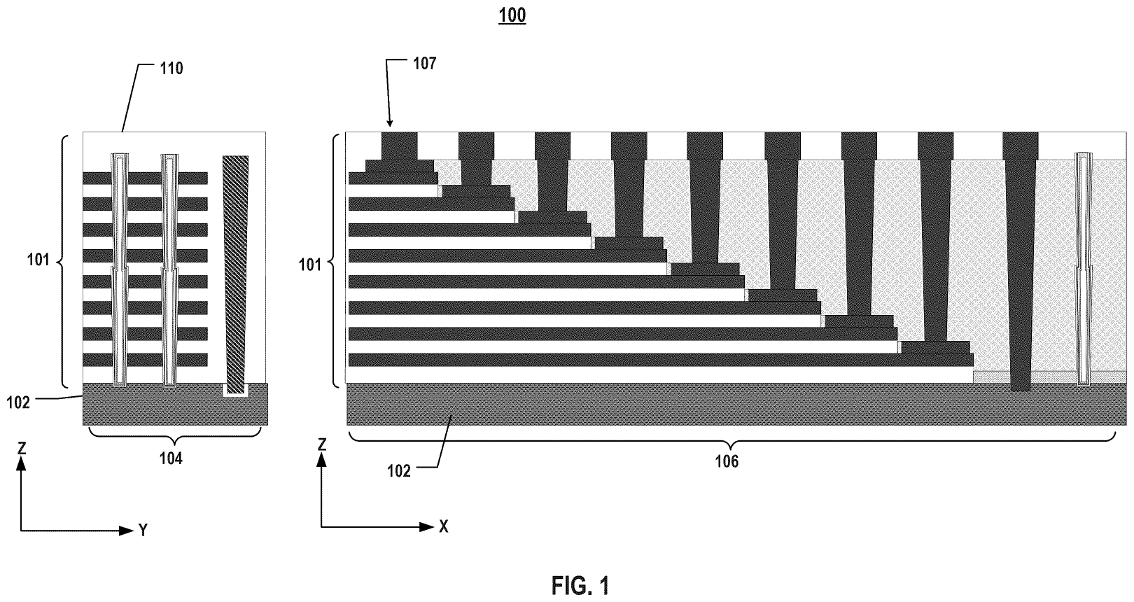

FIG. 1 illustrates a cross-sectional side view of a 3D memory device 100 having a staircase structure, according to some examples of the present disclosure. In some implementations, 3D memory device 100 is a NAND Flash memory device in which memory cells are provided in the form of an array of NAND memory strings. 3D memory device 100 may be divided into at least a core array region 104 and a staircase region 106. In some implementations, 3D memory device 100 may include a staircase structure formed in staircase region 106 for purposes such as word line pick-up/fan-out using word line contacts 107 landed onto different steps/levels of the staircase structure.

3D memory device 100 may include a substrate 102 and a stack structure 101 formed over substrate 102. An array of channel structures 110 may extend through stack structure 101 in core array region 104. Stack structure 101 can be formed by a plurality of stack segments, where a plurality of channel openings are formed in each stack segment. When the plurality of stack segments are stacked together to form stack structure 101, channel openings in the different stack segments are combined to form respective channel holes. Then, channel structures 110 can be formed in the channel holes, respectively. As the number of stack segments in stack structure 101 increases (e.g., as a total number of layers in stack structure 101 increases), a channel current of channel structure 110 is diminished.

On the other hand, word line contacts 107 are formed after the plurality of stack segments are stacked together. To form word line contacts 107, word line contact holes extending in a vertical direction (e.g., the z-direction) are formed by etching dielectric materials (e.g., silicon oxide) filled in staircase region 106. Bottoms of the word line contact holes are landed on different levels of the staircase structure, so that when word line contacts 107 are respectively formed in the word line contact holes, word line contacts 107 can be landed onto different steps/levels of the staircase structure to achieve the word line pick-up/fan-out function.

When the total number of layers increases in stack structure 101, the difficulty of etching the dielectric materials to form the word line contact holes in staircase region 106 may increase significantly, and the diameters of some word line contact holes may need to expand in order to etch deeper layers in staircase region 106. As a result, an area occupied by word line contacts 107 may increase, causing an area occupied by channel structures 110 to be reduced. As a result, the storage density in 3D memory device 100 is reduced.

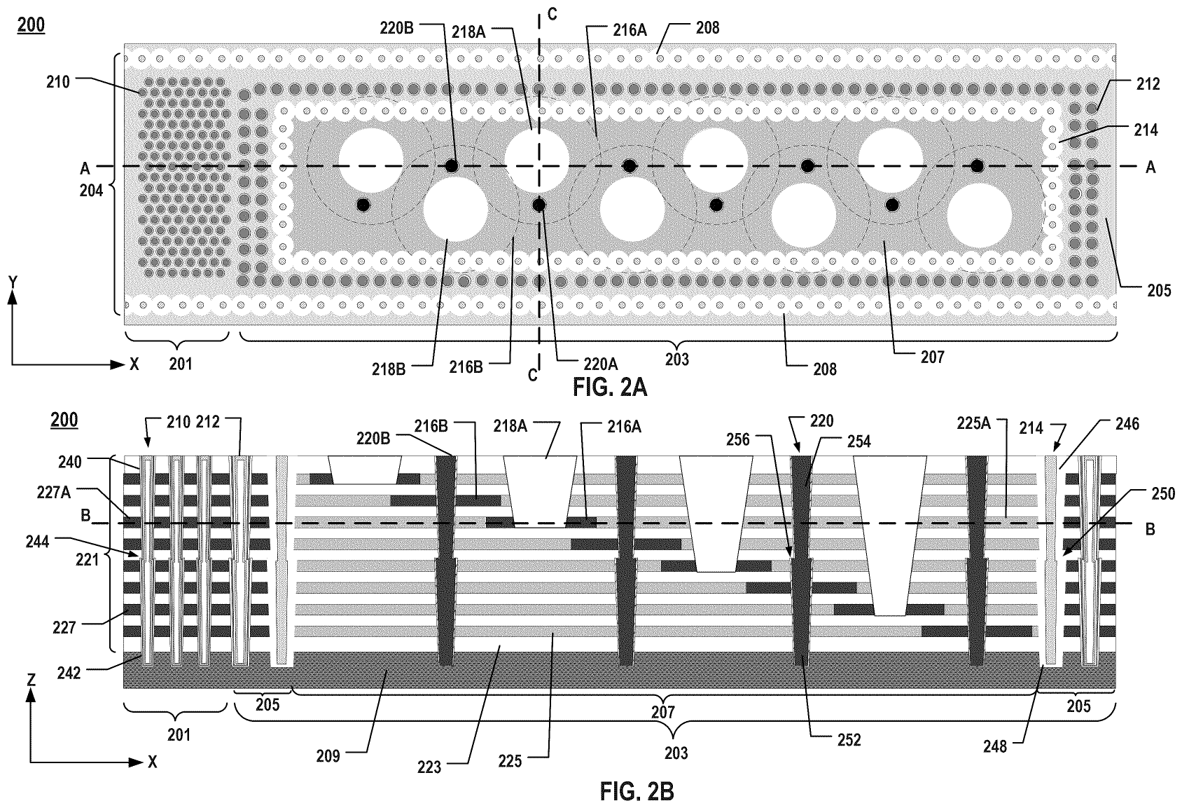

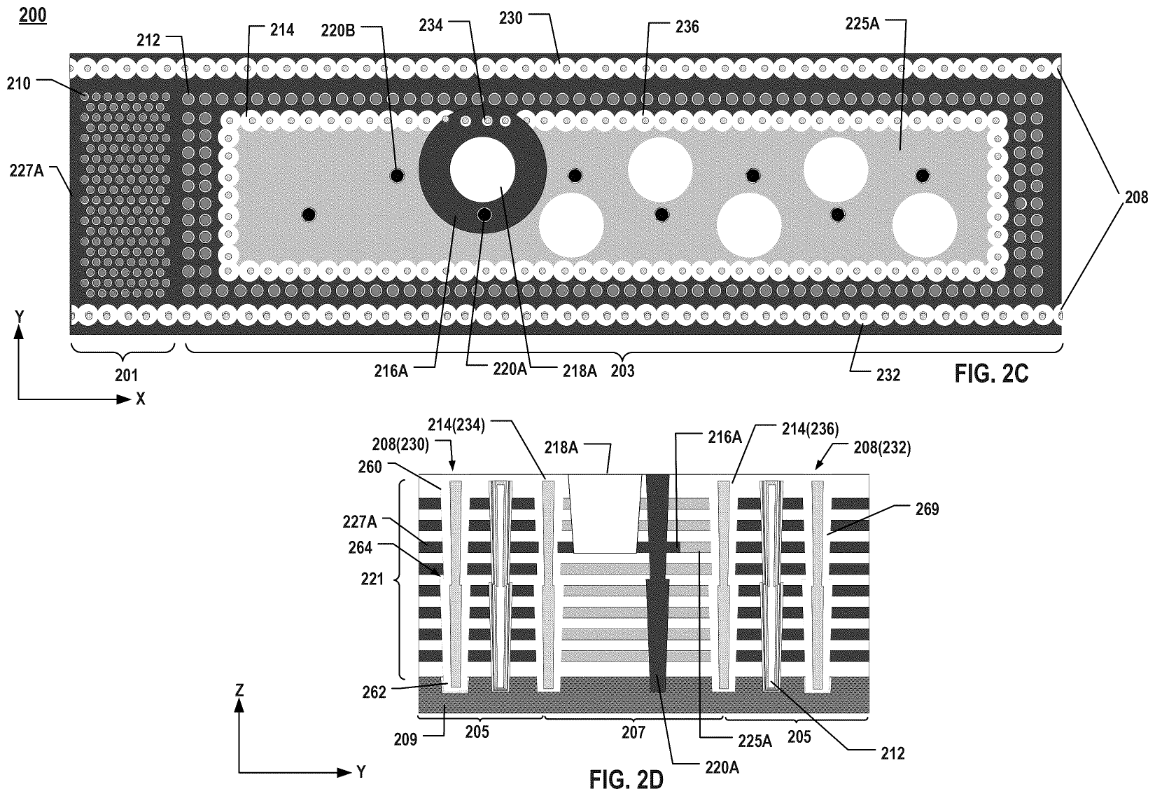

FIG. 2A illustrates a plan view of a 3D memory device 200 having contact structures 220 (e.g., 220A, 220B), according to some aspects of the present disclosure. FIG. 2B illustrates a cross-sectional side view of 3D memory device 200 of FIG. 2A, according to some aspects of the present disclosure. The cross-section of FIG. 2B is along the AA direction shown in FIG. 2A. FIG. 2C illustrates a cross-sectional view of 3D memory device 200 of FIG. 2A, according to some aspects of the present disclosure. The cross-section of FIG. 2C is along the BB direction shown in FIG. 2B. FIG. 2D illustrates another cross-sectional side view of the 3D memory device of FIG. 2A, according to some aspects of the present disclosure. The cross-section of FIG. 2D is along the CC direction shown in FIG. 2A. FIGS. 2A-2D are described together.

In some implementations, 3D memory device 200 is a NAND Flash memory device in which memory cells are provided in the form of an array of NAND memory strings. It is noted that x and y axes are included in FIG. 2A to illustrate two orthogonal (perpendicular) directions in the wafer plane. The x-direction is the word line direction of 3D memory device 200, and the y-direction is the bit line direction of 3D memory device 200.

As shown in FIG. 2A, 3D memory device 200 can include one or more blocks 204 arranged in the y-direction (the bit line direction) separated by parallel slit structures 208, such as gate line slits (GLSs). In some implementations in which 3D memory device 200 is a NAND Flash memory device, each block 204 is the smallest erasable unit of the NAND Flash memory device.

As shown in FIG. 2A, 3D memory device 200 can be divided into at least a core array region 201 in which an array of channel structures 210 are formed, as well as a word line pick-up region 203 in which contact structures 220 are formed. Core array region 201 and word line pick-up region 203 are arranged in the x-direction (the word line direction), according to some implementations. It is understood that although one core array region 201 and one word line pick-up region 203 are illustrated in FIG. 2A, multiple core array regions 201 and/or multiple word line pick-up regions 203 may be included in 3D memory device 200, for example, one word line pick-up region 203 between two core array regions 201 in the x-direction, in other examples. It is also understood that FIG. 2A only illustrates portions of core array region 201 that are adjacent to word line pick-up region 203.

As shown in FIGS. 2A and 2B, word line pick-up region 203 can be divided into at least a conductive portion 205 and a dielectric portion 207. Dielectric portion 207 may be surrounded by conductive portion 205. As shown in FIGS. 2A and 2B, contact structures 220 (e.g., 220A, 220B) are disposed in dielectric portion 207, while dummy channel structures 212 are disposed in conductive portion 205 to provide mechanical support and/or load balancing, according to some implementations. An isolation structure 214 may be formed between dielectric portion 207 and conductive portion 205 in word line pick-up region 203 to isolate dielectric portion 207 from (1) conductive portion 205 of word line pick-up region 203 and (2) core array region 201.

As shown in FIG. 2B, 3D memory device 200 may include a stack structure 221, which may include a first portion and a second portion adjacent to the first portion. The first portion of stack structure 221 may include a part of stack structure 221 in dielectric portion 207 of word line pick-up region 203. The second portion of stack structure 221 may include another part of stack structure 221 in (1) conductive portion 205 of word line pick-up region 203 and (2) core array region 201.

Stack structure 221 may include alternating first layers and first dielectric layers 223. For example, stack structure 221 can include vertically interleaved first layers and first dielectric layers 223. First layers and first dielectric layers 223 can alternate in the vertical direction (the z-direction). In some implementations, stack structure 221 can include a plurality of material layer pairs stacked vertically in the z-direction, each of which includes a first layer and a first dielectric layer 223. The number of the material layer pairs in stack structure 221 can determine the number of memory cells in 3D memory device 200.

The first layers in the first portion of stack structure 221 may include second dielectric layers 225. That is, the first portion of stack structure 221 may include alternating first dielectric layers 223 and second dielectric layers 225, as shown in FIG. 2B. The first layers in the second portion of stack structure 221 may include conductive layers 227. That is, the second portion of stack structure 221 may include alternating first dielectric layers 223 and conductive layers 227, as shown in FIG. 2B.

In some implementations, 3D memory device 200 is a NAND Flash memory device, and stack structure 221 is a stacked storage structure through which NAND memory strings are formed. In some implementations, each conductive layer 227 in the second portion of stack structure 221 functions as a gate line of the NAND memory strings (in the forms of channel structures 210) in core array region 201, as well as a word line extending laterally from the gate line and ending in conductive portion 205 of word line pick-up region 203 for word line pick-up/fan-out through a conductive structure 216 and a contact structure 220. For example, as described below in more detail, the word lines (i.e., conductive layers 227) at different depths/level of the second portion of stack structure 221 each extend laterally in core array region 201 and conductive portion 205 of word line pick-up region 203, and are connected to respective conductive structures 216 at different depths/level of the first portion of stack structure 221. The respective conductive structures 216 are connected to corresponding contact structures 220, respectively, for word line pick-up/fan-out function.

Conductive layers 227 can include conductive materials including, but not limited to, tungsten (W), cobalt (Co), copper (Cu), aluminum (Al), titanium nitride (TiN), polycrystalline silicon (polysilicon), doped silicon, silicides, or any combination thereof. First dielectric layers 223 or second dielectric layers 225 can include dielectric materials including, but not limited to, silicon oxide, silicon nitride, silicon oxynitride, or any combination thereof. First dielectric layers 223 and second dielectric layers 225 can have different dielectric materials, such as silicon oxide and silicon nitride. In some implementations, conductive layers 227 include metals, such as tungsten, first dielectric layers 223 include silicon oxide, and second dielectric layers 225 include silicon nitride. For example, first dielectric layers 223 of stack structure 221 may include silicon oxide across core array region 201 and word line pick-up region 203, whereas the first layers of stack structure 221 may include tungsten in core array region 201 and conductive portion 205 of word line pick-up region 203, and may include silicon nitride in dielectric portion 207 of word line pick-up region 203.

In some implementations, stack structure 221 may be formed over a semiconductor layer 209, such as a substrate. The substrate can include silicon (e.g., single crystalline silicon), silicon germanium (SiGe), gallium arsenide (GaAs), germanium (Ge), silicon on insulator (SOI), or any other suitable materials. In some implementations, the substrate includes single crystalline silicon, which is part of the wafer on which 3D memory device 200 is fabricated, either in its native thickness or being thinned. In some implementations, the substrate includes, for example, polysilicon, which is a semiconductor layer replacing the part of the wafer on which 3D memory device 200 is fabricated.

It is noted that x, y, and z axes are included in FIGS. 2A-2D to illustrate the spatial relationship of the components in 3D memory device 200. Semiconductor layer 209 (e.g., the substrate) of 3D memory device 200 includes two lateral surfaces extending laterally in the x-y plane: a top surface on the front side of the wafer on which stack structure 221 can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of 3D memory device 200 is determined relative to semiconductor layer 209 of 3D memory device 200 in the z-direction (the vertical direction perpendicular to the x-y plane) when semiconductor layer 209 is positioned in the lowest plane of 3D memory device 200 in the z-direction. The same notion for describing the spatial relationship is applied throughout the present disclosure.

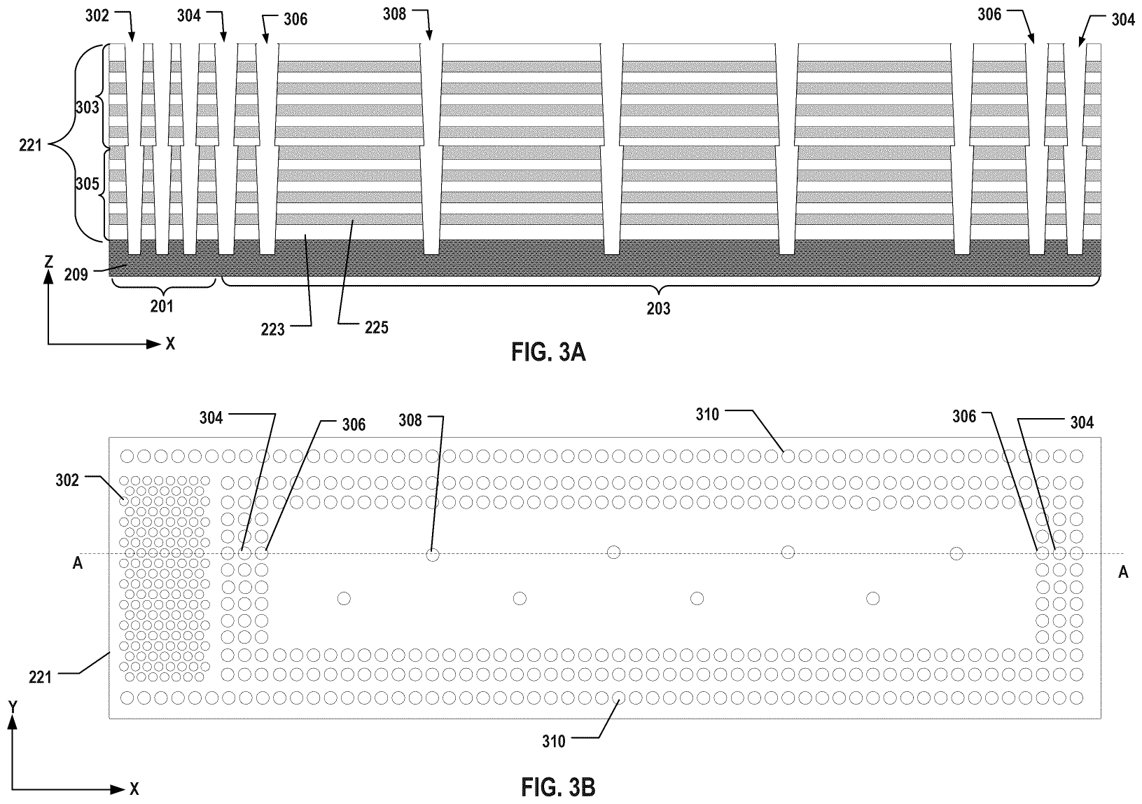

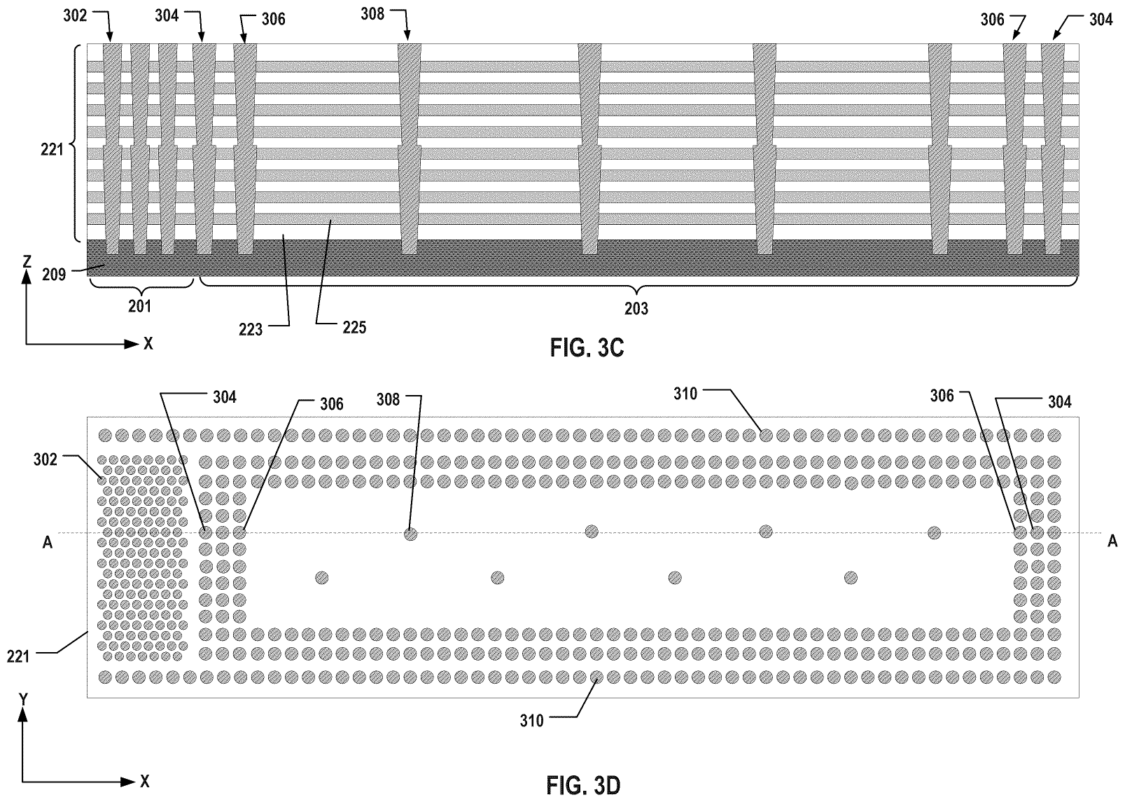

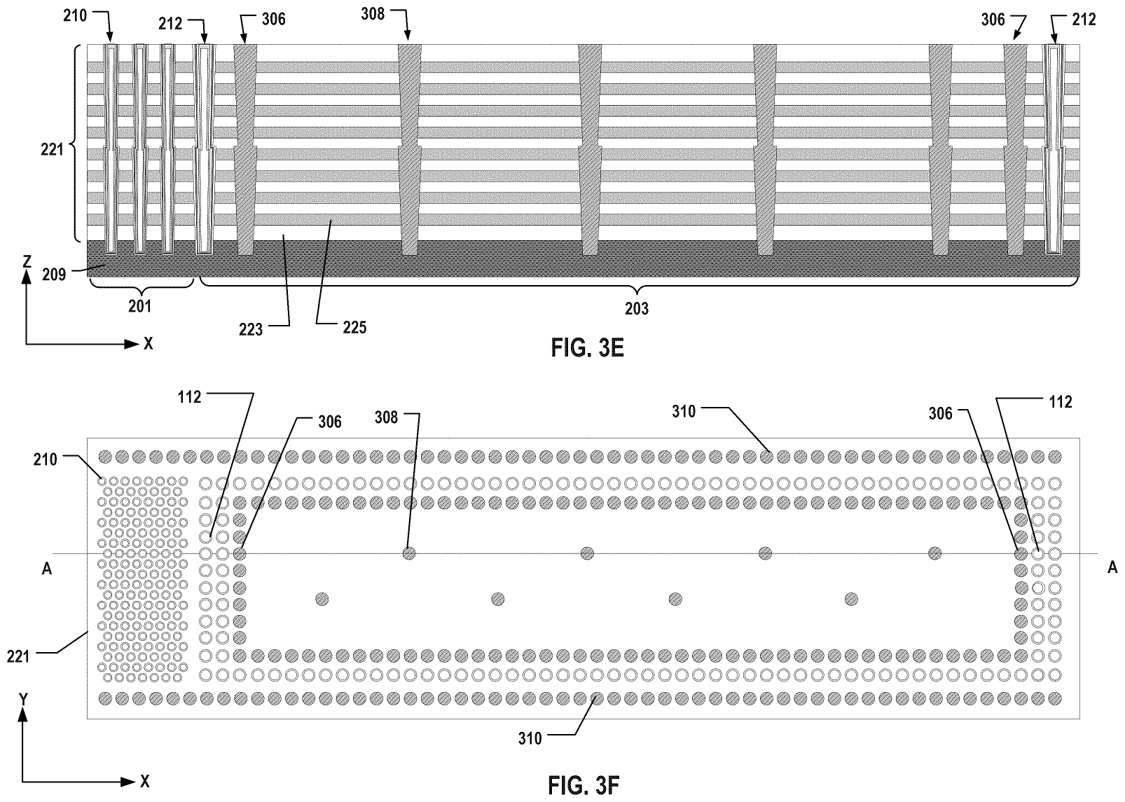

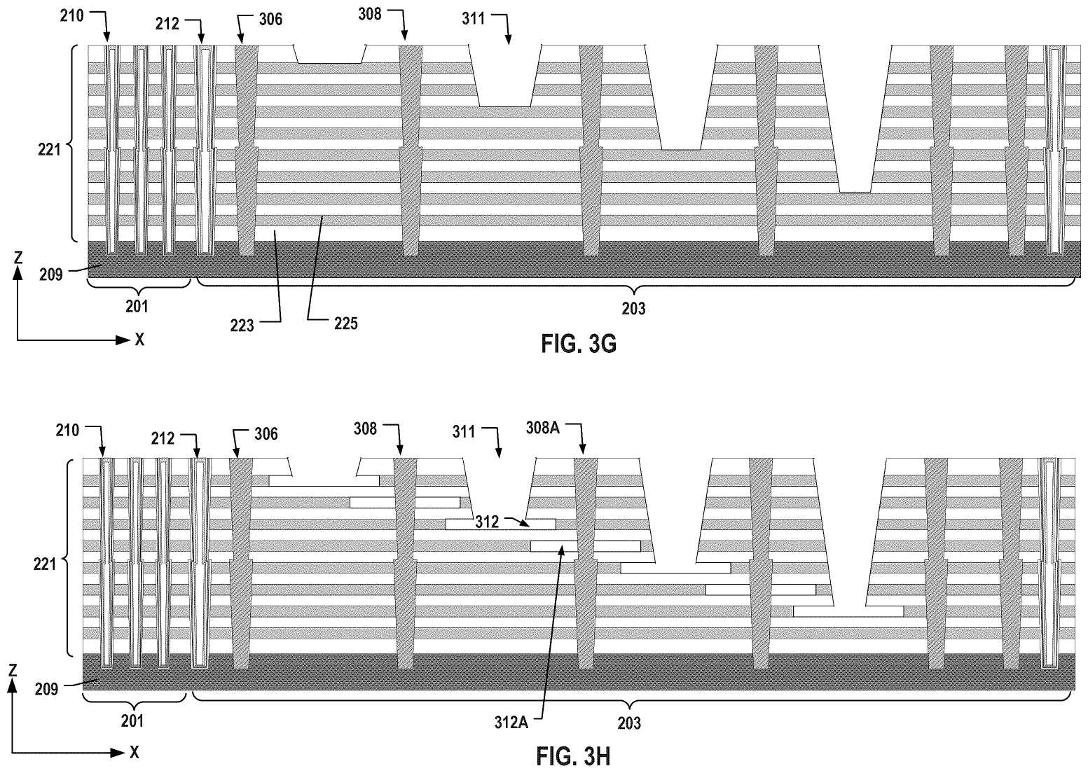

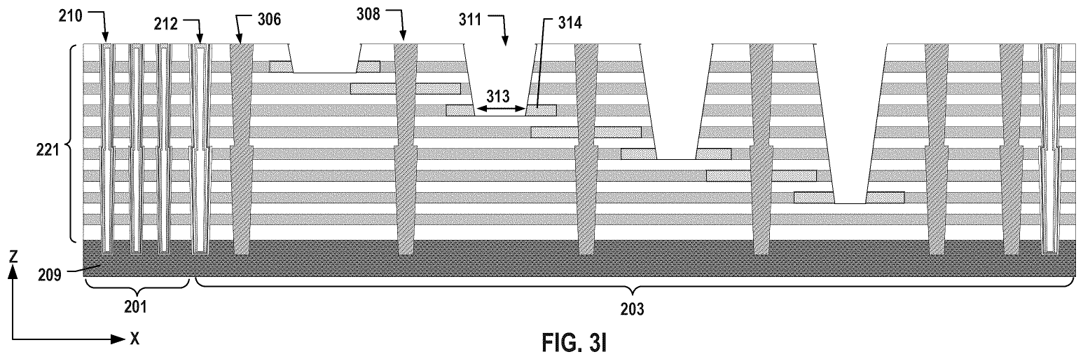

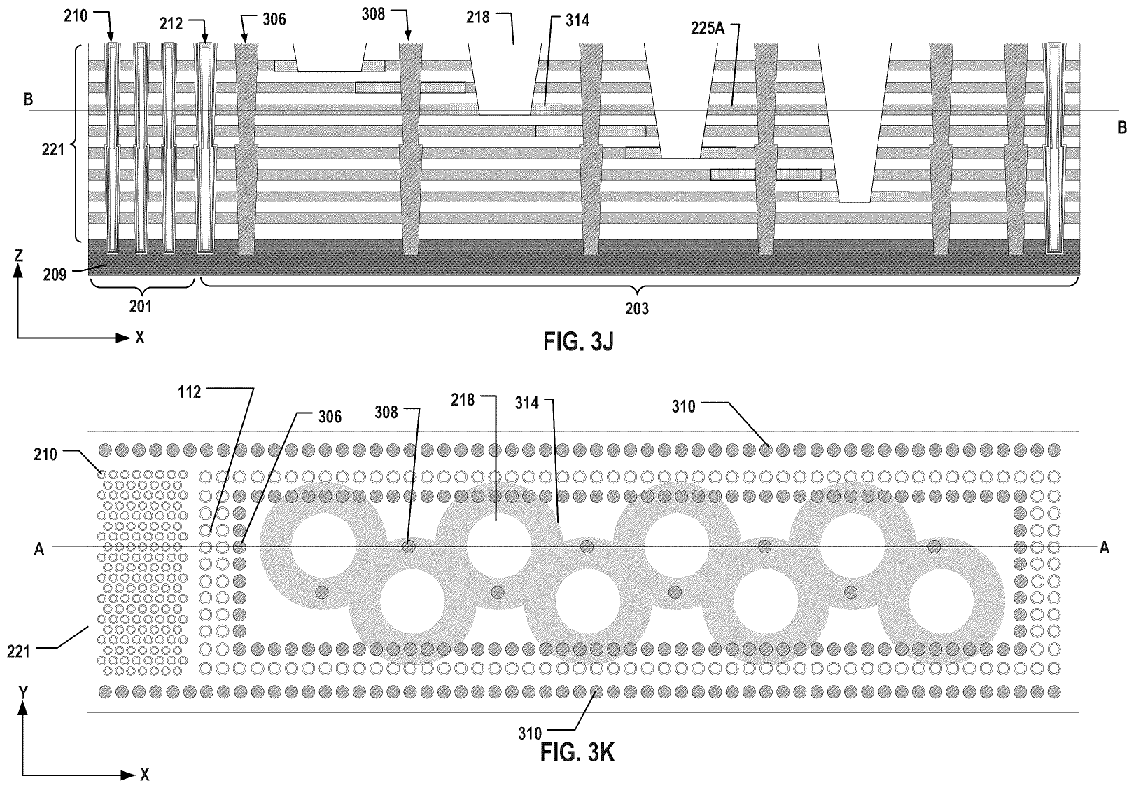

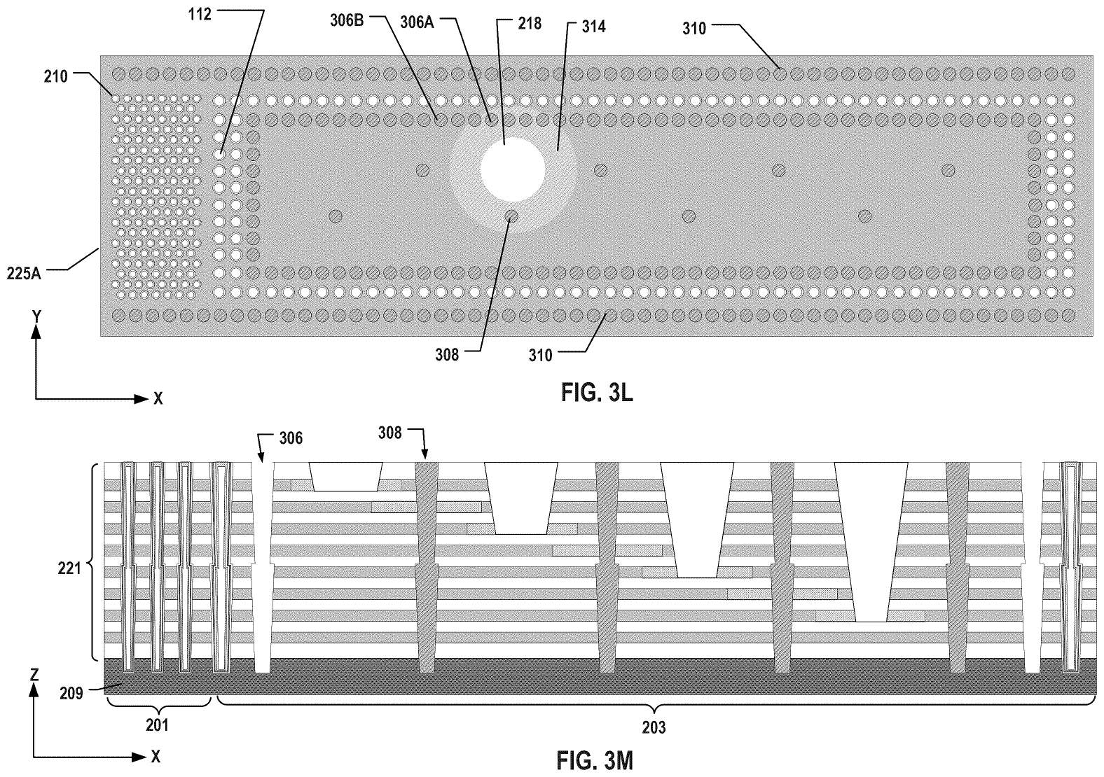

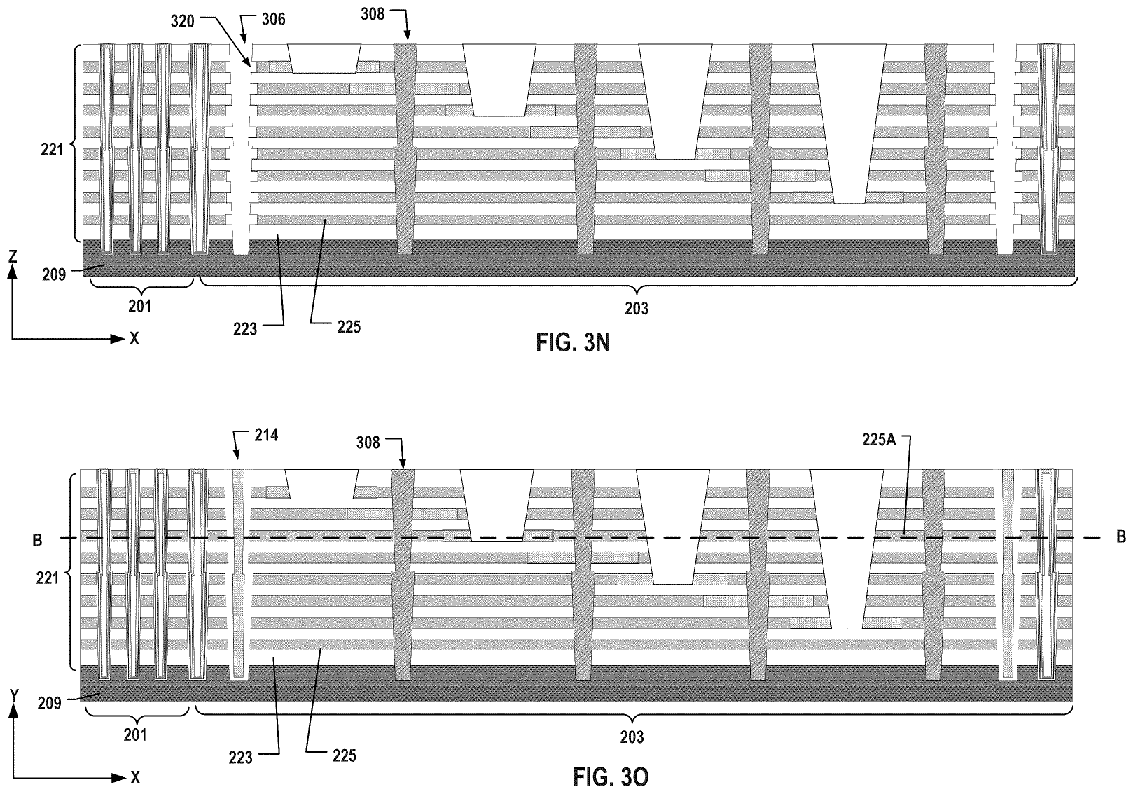

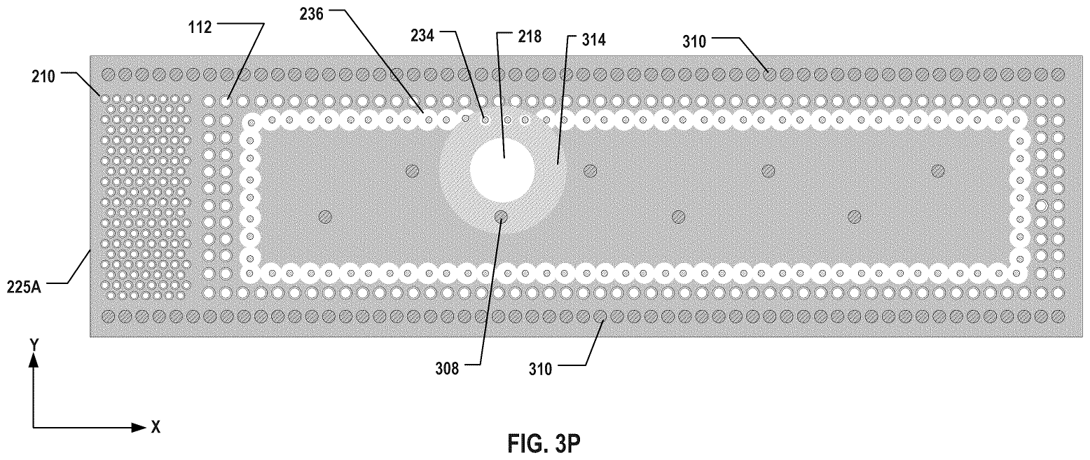

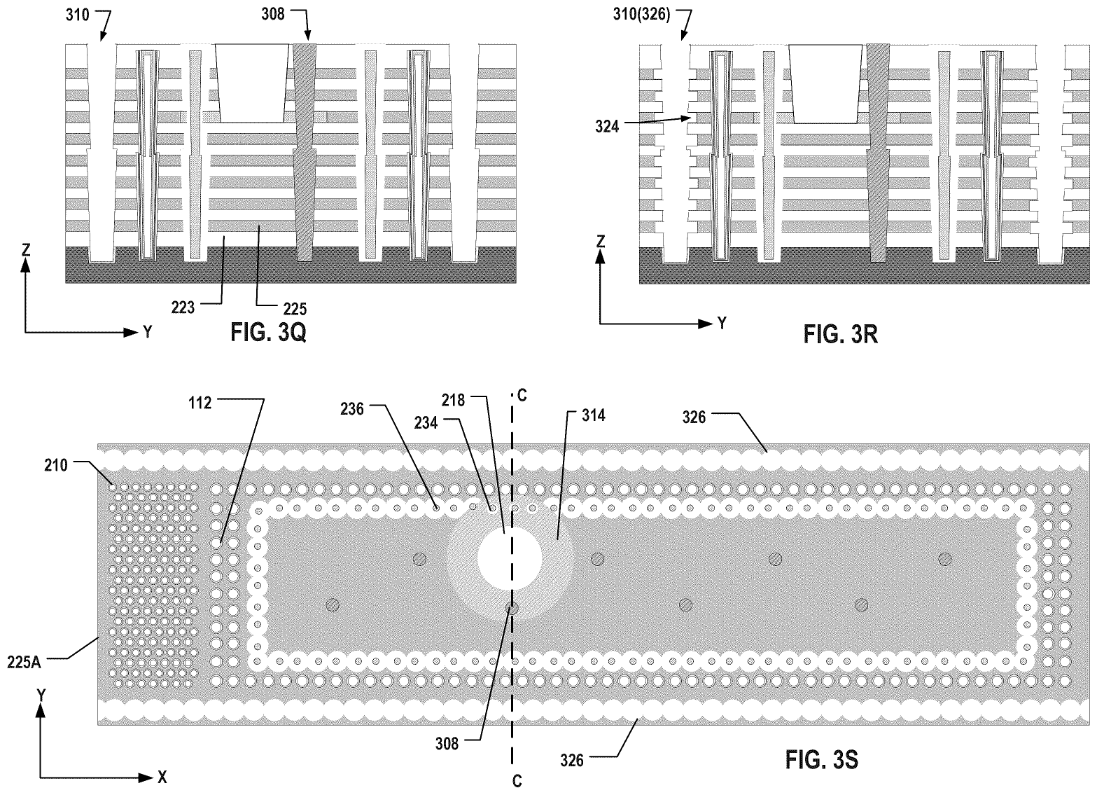

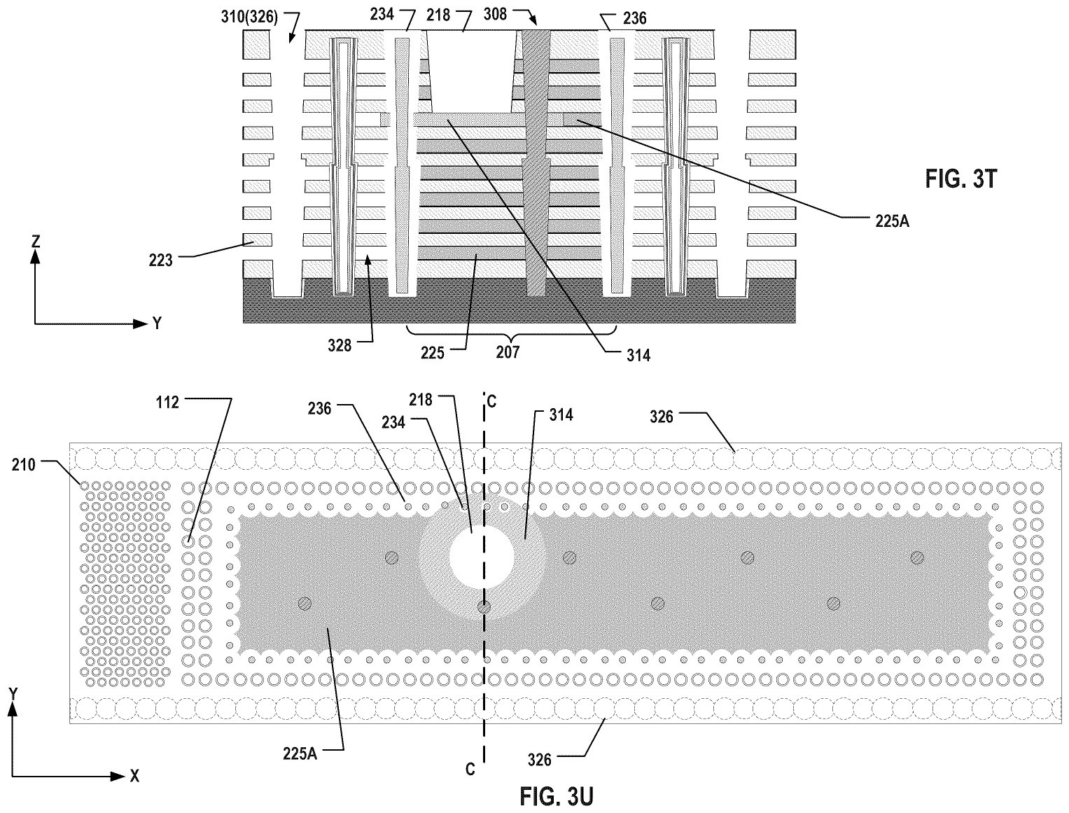

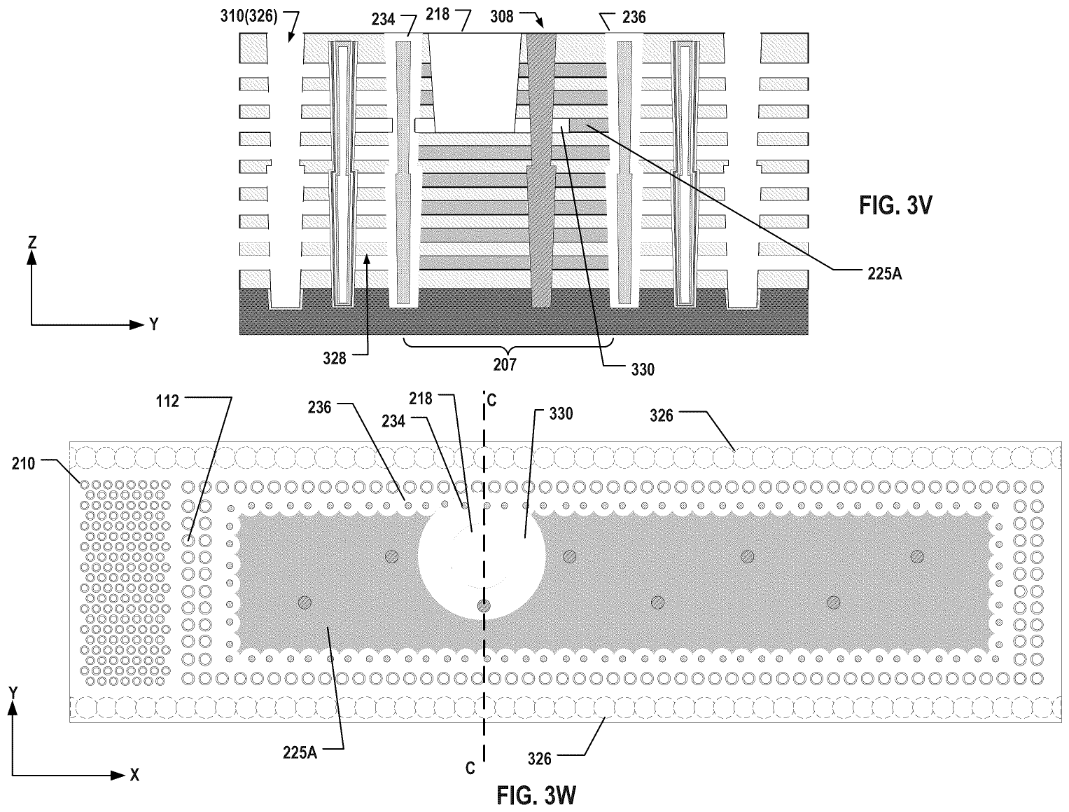

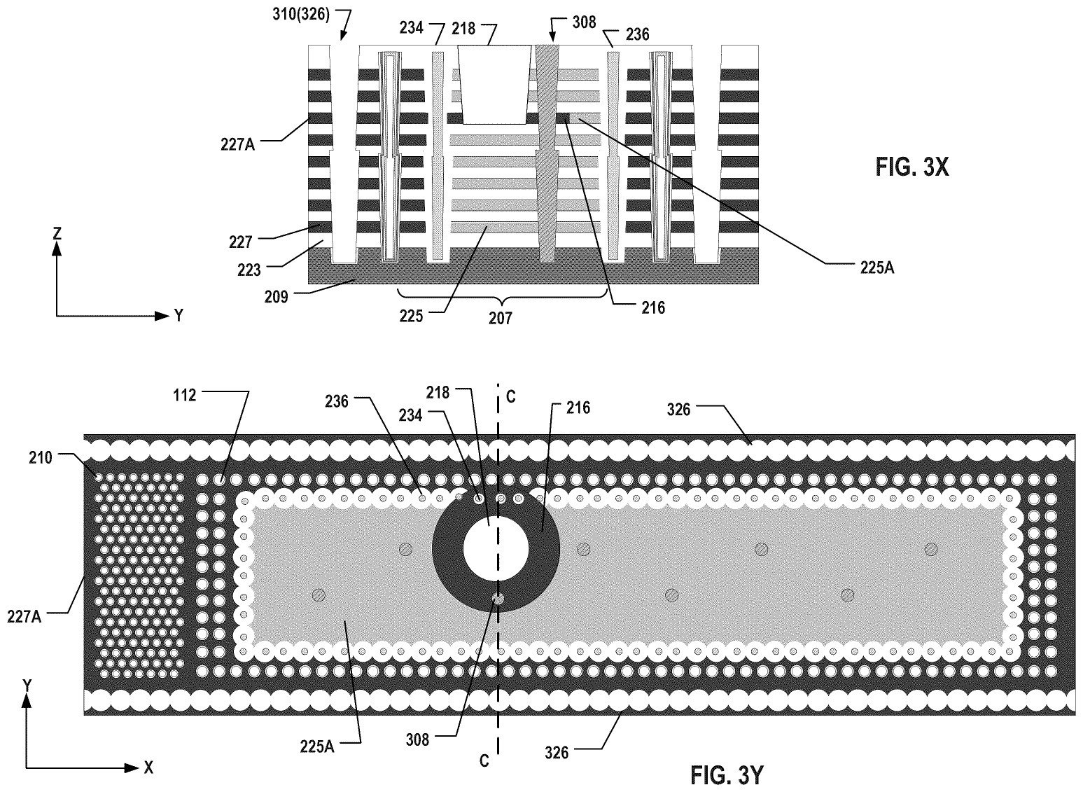

As shown in FIGS. 2A and 2B, 3D memory device 200 can include channel structures 210 in core array region 201. Each channel structure 210 can extend vertically through interleaved conductive layers 227 (word lines, e.g., tungsten) and first dielectric layers 223 (e.g., silicon oxide) in core array region 201 of stack structure 221 into semiconductor layer 209. 3D memory device 200 can also include dummy channel structures 212 in conductive portion 205 of word line pick-up region 203. Each dummy channel structure 212 can extend vertically through interleaved conductive layers 227 and first dielectric layers 223 in core array region 201 into semiconductor layer 209. 3D memory device 200 can further include slit structures 208 across core array region 201 and core array region 201. Each slit structure 208 can extend vertically through interleaved conductive layers 227 and first dielectric layers 223 in the second portion of stack structure 221 into semiconductor layer 209 as well.

As shown in FIG. 2D, slit structure 208 can include a slit spacer 269 that separates conductive layers 227 (word lines) between different blocks 204. In some implementations, slit structure 208 is an insulating structure that does not include any contact therein (i.e., not functioning as the source contact) and thus, does not introduce parasitic capacitance and leakage current with conductive layers 227 (word lines). In some implementations, slit structure 208 is a front-side source contact further including a conductive portion (e.g., including W, polysilicon, and/or TiN) circumscribed by slit spacer 269. Slit spacer 269 can include dielectric materials including, but not limited to, silicon oxide, silicon nitride, silicon oxynitride, or any combination thereof. As described below in detail, during the gate replacement process, the slit holes in which slit members of slit structure 208 are formed can serve as the passageway and starting point for forming conductive layers 227. As a result, slit structure 208 is surrounded by conductive layers 227 in either core array region 201 or conductive portion 205 of word line pick-up region 203.

In some implementations, channel structure 210 includes a channel hole filled with a semiconductor layer (e.g., as a channel layer) and a composite dielectric layer (e.g., as a memory layer). In some implementations, the channel layer includes silicon, such as amorphous silicon, polysilicon, or single crystalline silicon. For example, the channel layer may include polysilicon. In some implementations, the memory layer is a composite layer including a tunneling layer, a storage layer (also known as a “charge trap layer”), and a blocking layer. The remaining space of the channel hole can be partially or fully filled with a filler including dielectric materials, such as silicon oxide, and/or an air gap. Channel structure 210 can have a cylinder shape (e.g., a pillar shape). The filler, the channel layer, the tunneling layer, the storage layer, and the blocking layer are arranged radially from the center toward the outer surface of the pillar in this order, according to some implementations. The tunneling layer can include silicon oxide, silicon oxynitride, or any combination thereof. The storage layer can include silicon nitride, silicon oxynitride, silicon, or any combination thereof. The blocking layer can include silicon oxide, silicon oxynitride, or any combination thereof. In one example, the memory layer can include a composite layer of silicon oxide/silicon oxynitride/silicon oxide (ONO).

In some implementations, 3D memory device 200 can further include high dielectric constant (high-k) gate dielectric layers each sandwiched between adjacent conductive layer 227 and first dielectric layer 223 in core array region 201 and conductive portion 205 of word line pick-up region 203. As described below in detail with respect to the fabrication process, high-k gate dielectric layers may be formed prior to the formation of conductive layers 227 and conductive structures 216, such that conductive layers 227 and conductive structures 216 may be formed to be surrounded by high-k gate dielectric layers. High-k gate dielectric layers can include high-k dielectric materials, such as aluminum oxide (AlO), hafnium oxide (HfO), zirconium oxide (ZrO), or any combinations thereof. As described below in detail with respect to the fabrication process, compared with other high-k gate dielectric layers, part of high-k gate dielectric layer surrounding conductive structure 216 that is in contact with contact structure 220 is removed to expose conductive structure 216 such that contact structure 220 can be electrically connected to conductive structure 216.

In some implementations, dummy channel structure 212 has the same structure as channel structure 210 because they are formed in the same fabrication process. Dummy channel structure 212 may not perform the same memory functions as channel structure 210. It is understood that in some examples, dummy channel structures 212 and channel structure 210 may have different structures and may be formed in different fabrication processes. For example, dummy channel structures 212 may be filled with dielectric material(s) without semiconductor materials (as the channel layer). Nevertheless, both dummy channel structures 212 and channel structures 210 can perform the mechanical supporting functions to stack structure 221, in particular, during the gate replacement process, as described below in detail with respect to the fabrication processes.

3D memory device 200 may further include an isolation structure 214, conductive structures 216 (e.g., 216A, 216B), contact structures 220 (e.g., 220A, 220B), and dielectric structures 218 (e.g., 218A, 218B). As shown in FIG. 2A, conductive structures 216 and contact structures 220 are arranged alternately in the x-direction. Contact structures 220 are arranged in a staggered manner, and may have a one-to-one correspondence to conductive structures 216 and dielectric structures 218. For example, contact structure 220A may correspond to conductive structure 216A and dielectric structure 218A. Contact structure 220A may extend through conductive structure 216A outside dielectric structure 218A, and may be connected to conductive structure 216A (e.g., as shown in FIG. 2C or 2D). Similarly, contact structure 220B may correspond to conductive structure 216B and dielectric structure 218B. Contact structure 220B may extend through conductive structure 216B outside dielectric structure 218B, and may be connected to conductive structure 216B. It is understood that the layout and arrangement of contact structures 220, conductive structures 216, and dielectric structures 218, as well as the shape of each contact structure 220, the shape of each conductive structure 216, and the shape of each dielectric structure 218, may vary in different examples, which is not limited herein.

With reference to FIGS. 2A-2B, isolation structure 214 extends through stack structure 221 into semiconductor layer 209, and is located between the first portion and the second portion of stack structure 221 to isolate the first portion from the second portion. For example, as shown in FIG. 2A, isolation structure 214 surrounds the first portion of stack structure 221. Isolation structure 214 can include dielectric materials including, but not limited to, silicon oxide, silicon nitride, silicon oxynitride, or any combination thereof.

Conductive structures 216 (e.g., 216A or 216B) may be formed in second dielectric layers 225 in the first portion of stack structure 221. In some implementations, each conductive structure 216 may have a ring shape or any other suitable shape. For example, each conductive structure 216 is formed in a corresponding second dielectric layer 225 in a same layer as a conductive layer 227, and is connected to conductive layer 227 (e.g., as shown in FIG. 2C). Each conductive structure 216 includes a first part in the first portion of stack structure 221 (e.g., in dielectric portion 207 of word line pick-up region 203) and a second part in the second portion of stack structure 221 (e.g., in conductive portion 205 of word line pick-up region 203). Conductive structure 216 can include conductive materials including, but not limited to, W, Co, Cu, Al, TiN, polysilicon, doped silicon, silicides, or any combination thereof.

Contact structures 220 extend vertically through stack structure 221 in dielectric portion 207 of word line pick-up region 203 into semiconductor layer 209. For example, contact structures 220 may extend through the first portion of stack structure 221 in the z-direction and connect to corresponding conductive structures 216 at different depths/level of the first portion of stack structure 221, respectively. For example, each contact structure 220 may extend through a part of a corresponding conductive structure 216 in the first portion of stack structure 221, and may be in contact with the corresponding conductive structure 216. Contact structure 220 can include conductive materials including, but not limited to, W, Co, Cu, Al, TiN, polysilicon, doped silicon, silicides, or any combination thereof.

As shown in FIG. 2B, dielectric structures 218 extend into the first portion of stack structure 221 in a same direction as contact structures 220. For example, dielectric structures 218 extend vertically into stack structure 221 in dielectric portion 207 of word line pick-up region 203 at different depths in the z-direction, according to some implementations. The top surfaces of different dielectric structures 218 can be flush with one another, while the bottom surfaces of different dielectric structures 218 can extend to different levels, for example, different second dielectric layers 225 of stack structure 221. In some implementations, each dielectric structure 218 extends through the part of the corresponding conductive structure 216 in the first portion of stack structure 221, and a bottom portion of dielectric structure 218 is surrounded by the part of conductive structure 216. For example, dielectric structure 218A extends through a part of conductive structure 216A in dielectric portion 207 of word line pick-up region 203, and a bottom portion of dielectric structure 218A is surrounded by the part of conductive structure 216A.

In some implementations, dielectric structure 218 may have a pillar shape or any other suitable shape. Dielectric structure 218 can include dielectric materials including, but not limited to, silicon oxide, silicon nitride, silicon oxynitride, or any combination thereof. Dielectric structure 218 may include a dielectric material different from that of second dielectric layer 225. In some implementations, contact structure 220 can include TiN/W, dielectric structure 218 and first dielectric layer 223 can include silicon oxide, and second dielectric layer 225 can include silicon nitride.

Referring to FIGS. 2C and 2D, conductive structure 216A is formed in second dielectric layer 225A, which is in a same layer as conductive layer 227A. Conductive structure 216A is connected to conductive layer 227A. A first part of conductive structure 216A is in the first portion of stack structure 221 to connect to contact structure 220A, whereas a second part of conductive structure 216A is in the second portion of stack structure 221 to connect to conductive layer 227A. For example, conductive structure 216A extends through isolation structure 214 to connect to conductive layer 227A in the second portion of stack structure 221, whereas contact structure 220A extends through and is in contact with conductive structure 216A in the first portion of stack structure 221. As a result, an electrical connection is established between contact structure 220A and conductive layer 227A through conductive structure 216A.

As shown in FIGS. 2C-2D, isolation structure 214 may include (1) one or more first isolation members 234 extending into stack structure 221 through conductive structure 216A and (2) second isolation members 236 extending into stack structure 221 outside conductive structure 216A. In the cross section of isolation structure 214 in a lateral plane shown in FIG. 2C, first isolation members 234 are surrounded by and separated by conductive structure 216A. Second isolation members 236 are connected to one another to isolate conductive layer 227A from second dielectric layer 225A, which is in the same layer as conductive layer 227A. For example, in the cross section shown in FIG. 2C, second isolation members 236 are connected to one another to form an isolation wall. The isolation wall includes two sidewalls, with each sidewall including a plurality of arc surfaces connected to one another. However, in another cross section in another lateral plane of a different second dielectric layer 225 (e.g., a second dielectric layer 225 with the absence of conductive structure 216A), first isolation members 234 are also connected to one another to form an isolation wall, where each sidewall of the isolation wall also includes a plurality of arc surfaces connected to one another. That is, in another cross section with the absence of conductive structure 216A, first isolation members 234 may have a shape like that of second isolation members 236.

In some implementations as shown in FIGS. 2C-2D, slit structure 208 may include first slit members 230 and second slit members 232. First slit members 230 and second slit members 232 may extend through the second portion of stack structure 221. In the cross section of slit structure 208 shown in FIG. 2C, first slit members 230 are connected to one another, and second slit members 232 are also connected to one another. First slit members 230 and second slit members 232 may have the same shapes. For example, in the cross section shown in FIG. 2C, first slit members 230 are connected to one another to form a first slit wall. The first slit wall includes two sidewalls, with each sidewall including a plurality of arc surfaces connected to one another. Second slit members 232 are connected to one another to form a second slit wall. The second slit wall includes two sidewalls, with each sidewall including a plurality of arc surfaces connected to one another.

In some implementations with reference to FIG. 2C, dielectric structures 218 are located between first slit members 230 and second slit members 232. For example, dielectric structure 218A is located between first slit members 230 and second slit members 232. A first distance between dielectric structure 218A and first slit members 230 is smaller than a second distance between dielectric structure 218A and second slit members 232. Contact structure 220A, which extends through conductive structure 216A and corresponds to dielectric structure 218A, is located between dielectric structure 218A and second slit members 232.

In some implementations with reference to FIG. 2B, each channel structure 210 may include a plurality of channel segments. For example, channel structure 210 may include a first channel segment 242 extending into semiconductor layer 209 and a second channel segment 240 connected to first channel segment 242. A first end of first channel segment 242 is away from second channel segment 240 and extends into semiconductor layer 209, a second end of first channel segment 242 is connected to a first end of second channel segment 240, and a second end of second channel segment 240 is away from first channel segment 242. In the x direction, a size of the first end of first channel segment 242 is smaller than a size of the second end of first channel segment 242, and a size of the first end of second channel segment 240 is smaller than the size of the second end of first channel segment 242 and a size of the second end of second channel segment 240. A channel-structure shoulder 244 may be formed at a location where the second end of first channel segment 242 is connected to the first end of second channel segment 240.

In some implementations, isolation structure 214 may include isolation members 234 and 236 as shown in FIG. 2C. With reference to FIG. 2B, each isolation member of isolation structure 214 may include a plurality of isolation segments corresponding to the plurality of channel segments, respectively. For example, each isolation member of isolation structure 214 may include a first isolation segment 248 extending into semiconductor layer 209 and a second isolation segment 246 connected to first isolation segment 248. A first end of first isolation segment 248 is away from second isolation segment 246 and extends into semiconductor layer 209, a second end of first isolation segment 248 is connected to a first end of second isolation segment 246, and a second end of second isolation segment 246 is away from first isolation segment 248. In the x direction, a size of the first end of first isolation segment 248 is smaller than a size of the second end of first isolation segment 248, and a size of the first end of second isolation segment 246 is smaller than the size of the second end of first isolation segment 248 and a size of the second end of second isolation segment 246. An isolation-structure shoulder 250 may be formed at a location where the second end of first isolation segment 248 is connected to the first end of second isolation segment 246.

In some implementations with reference to FIG. 2B, contact structure 220 may include a plurality of contact segments corresponding to the plurality of channel segments, respectively. For example, contact structure 220 may include a first contact segment 252 extending into semiconductor layer 209 and a second contact segment 254 connected to first contact segment 252. A first end of first contact segment 252 is away from second contact segment 254 and extends into semiconductor layer 209, a second end of first contact segment 252 is connected to a first end of second contact segment 254, and a second end of second contact segment 254 is away from first contact segment 252. In the x direction, a size of the first end of first contact segment 252 is smaller than a size of the second end of first contact segment 252, and a size of the first end of second contact segment 254 is smaller than the size of the second end of first contact segment 252 and a size of the second end of second contact segment 254. A contact-structure shoulder 256 may be formed at a location where the second end of first contact segment 252 is connected to the first end of second contact segment 254.

In some implementations, slit structure 208 may include slit members 230 and 232 as shown in FIG. 2C. With reference to FIG. 2D, each slit member of slit structure 208 may include a plurality of slit segments corresponding to the plurality of channel segments, respectively. For example, each slit member of slit structure 208 may include a first slit segment 262 extending into semiconductor layer 209 and a second slit segment 260 connected to first slit segment 262. A first end of first slit segment 262 is away from second slit segment 260 and extends into semiconductor layer 209, a second end of first slit segment 262 is connected to a first end of second slit segment 260, and a second end of second slit segment 260 is away from first slit segment 262. In the x direction, a size of the first end of first slit segment 262 is smaller than a size of the second end of first slit segment 262, and a size of the first end of second slit segment 260 is smaller than the size of the second end of first slit segment 262 and a size of the second end of second slit segment 260. A slit-structure shoulder 264 may be formed at a location where the second end of first slit segment 262 is connected to the first end of second slit segment 260.

With combined reference to FIGS. 2A-2D, instead of having staircase structures and word line contacts landed on different levels/stairs of the staircase structures like 3D memory device 100 of FIG. 1, 3D memory device 200 can include stack structure 221 with uniform heights, and can include conductive structures 216 and contact structures 220 in dielectric portion 207 of word line pick-up region 203 for word line pick-up/fan-out. Each conductive structure 216 may extend laterally across conductive portion 205 and dielectric portion 207 of word line pick-up region 203, to be in contact with a corresponding conductive layer 227 (word line) in conductive portion 205 at the same level of stack structure 221 and to be in contact with a corresponding contact structure 220 in dielectric portion 207. Thus, the corresponding contact structure 220 is electrically connected to the corresponding conductive layer 227 (word line) through conductive portion 205, according to some implementations. In other words, different contact structures 220 can extend vertically through stack structure 221 to be electrically connected to the word lines at different levels through respective conductive structures 216, respectively, to achieve word line pick-up/fan-out.

It is contemplated that in some implementations semiconductor layer 209 shown in FIG. 2B includes a substrate which may be removed in subsequent processes, such as in processes after the formation of channel structures 210 or after the formation of contact structures 220. Then, an array common source (ACS) can be formed and connected to channel layers of channel structures 210. For example, the entire structure of memory device 200 shown in FIG. 2B can be flipped over so that the substrate on the bottom is flipped to the top of the structure. Next, a portion of each channel structure 210 which extends into the substrate can be exposed by removing the substrate from the flipped structure. A memory layer (e.g., an ONO composite layer) of the exposed portion of each channel structure 210 can also be removed to expose a channel layer of channel structure 210. Subsequently, a semiconductor layer can be deposited and formed on top of the flipped structure as an ACS to connect to the channel layer of each channel structure 210.

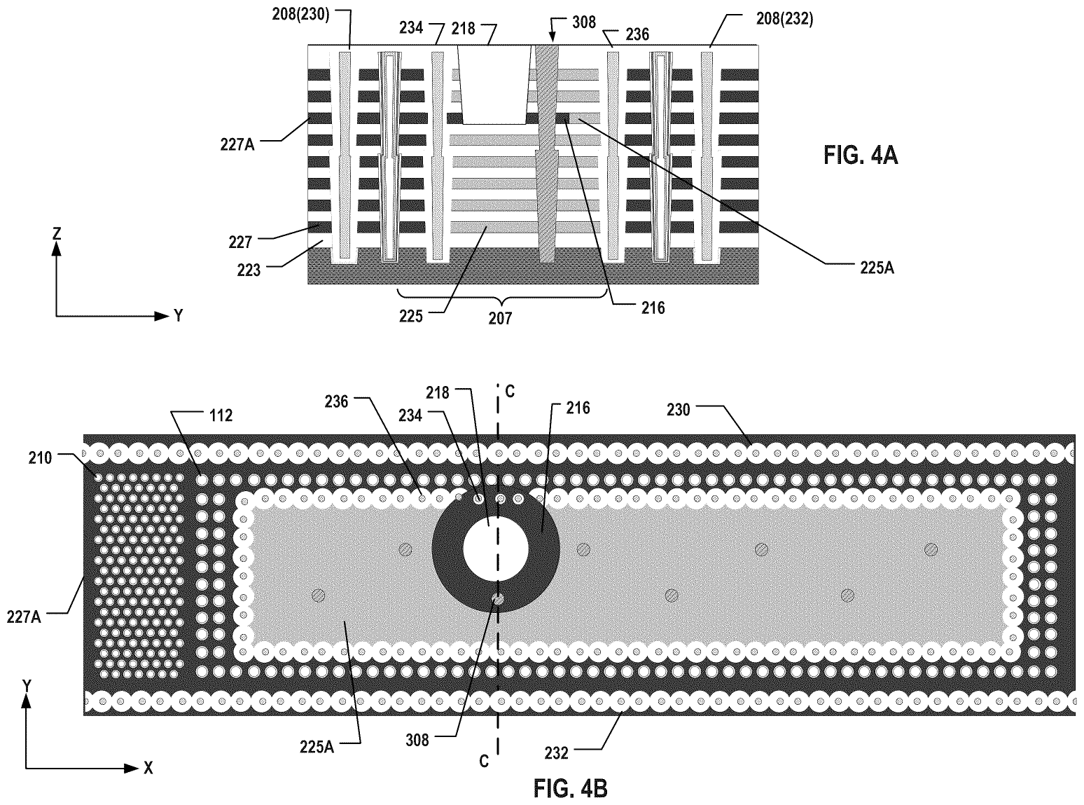

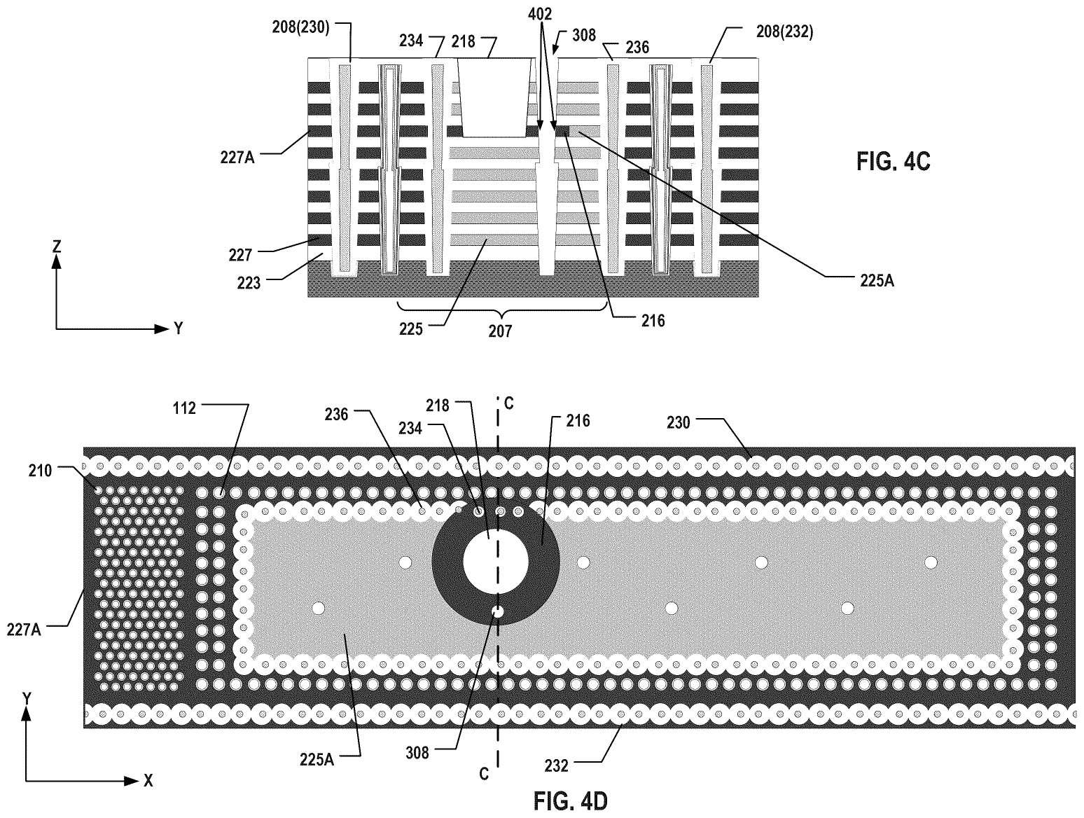

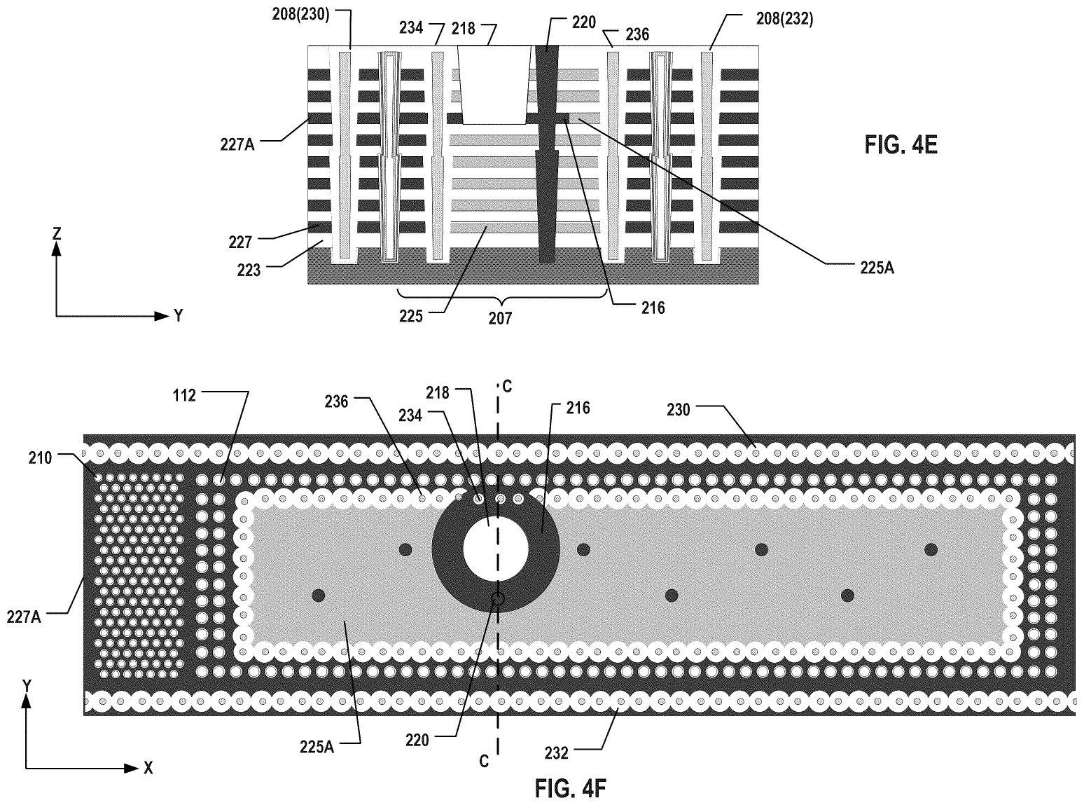

FIGS. 3A-3Y and 4A-4F illustrate a fabrication process for forming 3D memory device 100 having contact structures 220, according to some aspects of the present disclosure. FIG. 3A illustrates a cross-sectional side view of stack structure 221, and FIG. 3B illustrates a plan view of stack structure 221. FIG. 3A is along the AA direction of FIG. 3B. As illustrated in FIGS. 3A-3B, a plurality of channel holes 302, a plurality of dummy channel holes 304, a plurality of isolation holes 306, a plurality of contact holes 308, and a plurality of slit holes 310 are formed in stack structure 221.

As illustrated in FIG. 3A, stack structure 221 including multiple pairs of a first dielectric layer 223 and a second dielectric layer 225 (a.k.a., a stack sacrificial layer) is formed above semiconductor layer 209. Stack structure 221 includes vertically interleaved first dielectric layers 223 and second dielectric layers 225, according to some implementations. In some examples, each first dielectric layer 223 includes a layer of silicon oxide, and each second dielectric layer 225 includes a layer of silicon nitride.

In some implementations, first dielectric layers 223 and second dielectric layers 225 can be alternatingly deposited above semiconductor layer 209 to form stack structure 221. Stack structure 221 can be formed by one or more thin film deposition processes including, but not limited to, chemical vapor deposition (CVD), physical vapor deposition (PVD), atomic layer deposition (ALD), or any combination thereof.

Channel holes 302, each of which includes at least a channel opening extending vertically through stack structure 221, can be formed in core array region 201. In some implementations, a plurality of channel holes 302 are formed, such that each channel hole 302 becomes the location for growing an individual channel structure 210 in the later process. In some implementations, fabrication processes for forming channel holes 302 include wet etching and/or dry etching, such as deep-ion reactive etching (DRIE).

Dummy channel holes 304, each of which includes at least a dummy channel opening extending vertically through stack structure 221, can be formed in conductive portion 205 of word line pick-up region 203 simultaneously as channel holes 302 by the same wet etching and/or dry etching, such as DRIE. Each dummy channel hole 304 is a location for growing an individual dummy channel structure 212 in the later process.

Isolation holes 306, each of which includes at least an isolation opening extending vertically through stack structure 221, can be formed in word line pick-up region 203 (e.g., between conductive portion 205 and dielectric portion 207 of word line pick-up region 203) simultaneously as channel holes 302 by the same wet etching and/or dry etching, such as DRIE. Each isolation hole 306 is a location for growing an individual isolation member of isolation structure 214 in the later process.

Contact holes 308, each of which includes at least a contact opening extending vertically through stack structure 221, can be formed in dielectric portion 207 of word line pick-up region 203 simultaneously as channel holes 302 by the same wet etching and/or dry etching, such as DRIE. Each contact hole 308 is a location for growing an individual contact structure 220 in the later process.

Slit holes 310, each of which includes at least a slit opening extending vertically through stack structure 221, can be formed in core array region 201 and conductive portion 205 of word line pick-up region 203 simultaneously as channel holes 302 by the same wet etching and/or dry etching, such as DRIE. Each slit hole 310 is a location for growing an individual slit member of slit structure 208 in the later process.

In some implementations, stack structure 221 may include at least a first stack segment 305 and a second stack segment 303. First stack segment 305 may include a first subset of the alternating first dielectric layers 223 and second dielectric layers 225 over semiconductor layer 209. A plurality of first channel openings, a plurality of first dummy channel openings, a plurality of first isolation openings, a plurality of first slit openings, and a plurality of first contact openings may be formed in first stack segment 305 simultaneously using fabrication processes including wet etching and/or dry etching, such as DRIE.

Second stack segment 303 may include a second subset of the alternating first dielectric layers 223 and second dielectric layers 225. A plurality of second channel openings, a plurality of second dummy channel openings, a plurality of second isolation openings, a plurality of second slit openings, and a plurality of second contact openings may be formed in second stack segment 303 simultaneously using fabrication processes including wet etching and/or dry etching, such as DRIE.

First stack segment 305 can be combined with second stack segment 303 to form stack structure 221. For example, second stack segment 303 may be stacked over or bonded over first stack segment 305 to form stack structure 221. As a result, a plurality of channel holes 302 may be formed in stack structure 221 by combining the plurality of first channel openings with the plurality of second channel openings, respectively. That is, each first channel opening in first stack segment 305 is aligned with a respective second channel opening in second stack segment 303, and combined with the respective second channel opening to form a respective channel hole 302.

Similarly, a plurality of dummy channel holes 304 may be formed in stack structure 221 by combining the plurality of first dummy channel openings with the plurality of second dummy channel openings, respectively. That is, each first dummy channel opening in first stack segment 305 is aligned with a respective second dummy channel opening in second stack segment 303, and combined with the respective second dummy channel opening to form a respective dummy channel hole 304.

A plurality of isolation holes 306 may be formed in stack structure 221 by combining the plurality of first isolation openings with the plurality of second isolation openings, respectively. That is, each first isolation opening in first stack segment 305 is aligned with a respective second isolation opening in second stack segment 303, and combined with the respective second isolation opening to form a respective isolation hole 306.

A plurality of contact holes 308 may be formed in stack structure 221 by combining the plurality of first contact openings with the plurality of second contact openings, respectively. That is, each first contact opening in first stack segment 305 is aligned with a respective second contact opening in second stack segment 303, and combined with the respective second contact opening to form a respective contact hole 308.

A plurality of slit holes 310 may be formed in stack structure 221 by combining the plurality of first slit openings with the plurality of second slit openings, respectively. That is, each first slit opening in first stack segment 305 is aligned with a respective second slit opening in second stack segment 303, and combined with the respective second slit opening to form a respective slit hole 310.

As illustrated in FIGS. 3C-3D (e.g., FIG. 3C is a cross section along the AA direction of FIG. 3D, and FIG. 3D is a plan view of stack structure 221), channel holes 302, dummy channel holes 304, slit holes 310, isolation holes 306, and contact holes 308 may be filled with a first sacrificial material. For example, channel holes 302, dummy channel holes 304, slit holes 310, isolation holes 306, and contact holes 308 may be filled by depositing a first sacrificial material, such as carbon, into the holes using one or more thin film deposition processes, such as ALD, CVD, PVD, any other suitable processes, or any combination thereof.

As illustrated in FIGS. 3E-3F (e.g., FIG. 3E is a cross section along the AA direction of FIG. 3F, and FIG. 3F is a plan view of stack structure 221), the first sacrificial material filled in channel holes 302 and dummy channel holes 304 can be removed. The first sacrificial material filled in slit holes 310, isolation holes 306, and contact holes 308 remains intact. For example, the first sacrificial material can be patterned using lithography and wet etching and/or dry etching to remove the part of the first sacrificial material filled in channel holes 302 and dummy channel holes 304, leaving the part of the first sacrificial material filled in slit holes 310, isolation holes 306, and contact holes 308 intact.

Subsequently, channel structures 210 can be formed in channel holes 302 in core array region 201 of stack structure 221. A memory layer (including a blocking layer, a storage layer, and a tunneling layer) and a channel layer are sequentially formed in this order along sidewalls and the bottom surface of channel hole 302. In some implementations, the memory layer is first deposited along the sidewalls and bottom surface of channel hole 302, and the semiconductor channel is then deposited over the memory layer. The blocking layer, storage layer, and tunneling layer can be subsequently deposited in this order using one or more thin film deposition processes, such as ALD, CVD, PVD, any other suitable processes, or any combination thereof, to form the memory layer. The channel layer can then be formed by depositing a semiconductor material, such as polysilicon, over the tunneling layer of the memory layer using one or more thin film deposition processes, such as ALD, CVD, PVD, any other suitable processes, or any combination thereof. In some implementations, a first silicon oxide layer, a silicon nitride layer, a second silicon oxide layer, and a polysilicon layer (a “SONO” structure) are subsequently deposited to form the memory layer and the channel layer of channel structure 210.

Dummy channel structures 212 can also be formed in dummy channel holes 304 in word line pick-up region 203 of stack structure 221, in the same process as forming channel structures 210. Dummy channel structures 212 can be formed simultaneously as channel structures 210 by the same thin film deposition processes, such as ALD, CVD, PVD, any other suitable processes, or any combination thereof that deposit a memory layer (including a blocking layer, a storage layer, and a tunneling layer) and a channel layer. It is understood that in some examples, dummy channel structures 212 may be formed in a separate process from channel structures 210.

As illustrated in FIG. 3G, dielectric openings 311 may be formed in dielectric portion 207 of stack structure 221 to expose corresponding second dielectric layers 225 under dielectric openings 311. Dielectric openings 311 may have a one-to-one correspondence with contact holes 308. For example, stack structure 221 may be etched to form dielectric openings 311 having different depths in the z-direction, to expose corresponding second dielectric layers 225 under dielectric openings 311.

In some implementations, fabrication processes for forming dielectric openings 311 include wet etching and/or dry etching, such as DRIE. In some implementations, dielectric openings 311 can be formed using a chopping process. As used herein, a “chopping” process is a process that increases the depth of one or more openings extending through interleaved first and second dielectric layers by a plurality of etching cycles. Each etch cycle can include one or more dry etch and/or wet etch processes that etch one pair of first and second dielectric layers, i.e., reducing the depth by a layer pair including a first dielectric layer 223 and a second dielectric layer 225.

As illustrated in FIG. 3H, for each dielectric opening 311, a portion of second dielectric layer 225 exposed under dielectric opening 311 can be removed to form a lateral opening 312 in second dielectric layer 225. Lateral opening 312 extends laterally from dielectric portion 207 into conductive portion 205 of stack structure 221. For example, lateral opening 312 may have a disk shape, and may extend across dielectric portion 207 and conductive portion 205 of stack structure 221. In some implementations, for each lateral opening 312, there is only one contact hole 308 extending through lateral opening 312. For example, with respect to lateral opening 312A, only a contact hole 308A filled with the first sacrificial material extends through lateral opening 312A.

In some implementations, to form lateral opening 312 under dielectric opening 311, initially a spacer can be formed on a sidewall and a bottom surface of dielectric opening 311, thereby covering first dielectric layers 223 and second dielectric layers 225 exposed from the sidewall and bottom surface of dielectric opening 311. In some examples, the spacer is formed by depositing dielectric materials, such as silicon oxide, using one or more thin film deposition processes, such as ALD, CVD, PVD, any other suitable processes, or any combination thereof, over the sidewall and the bottom surface of dielectric opening 311.

Next, a part of the spacer on the bottom surface of dielectric opening 311 is removed, for example, by dry etching, to expose the part of second dielectric layer 225 under dielectric opening 311 in dielectric portion 207 of word line pick-up region 203. In some implementations, the etching rate, direction, and/or duration of RIE are controlled to etch only the part of the spacer on the bottom surface, but not on the sidewall, of dielectric opening 311, i.e., “punching” through the spacer in the z-direction to expose only a corresponding second dielectric layer 225 from the bottom, but not other second dielectric layers 225 from the sidewall.

Subsequently, the part of second dielectric layer 225 exposed from the bottom of dielectric opening 311 is removed by wet etching to form lateral opening 312. In some implementations, the part of second dielectric layer 225 is wet etched by applying a wet etchant through dielectric opening 311, creating lateral opening 312 sandwiched between two first dielectric layers 223. The wet etchant can include phosphoric acid for etching second dielectric layer 225 including silicon nitride. In some implementations, the etching rate and/or etching time are controlled to remove only a part of second dielectric layer 225 to make sure that lateral opening 312 can extend from dielectric portion 207 to conductive portion 205 of word line pick-up region 203. By controlling the etching time, the wet etchant does not travel all the way to completely remove second dielectric layer 225 in dielectric portion 207, such that there is only one contact hole 308 filled with the first sacrificial material extending through lateral opening 312 while lateral opening 312 can extend across dielectric portion 207 and conductive portion 205 of word line pick-up region 203. Since the sidewall of dielectric opening 311 is still covered by the spacer (e.g., silicon oxide) that is resistant to the etchant for removing second dielectric layers 225 (e.g., silicon nitride), second dielectric layers 225 at other levels remain intact.

As illustrated in FIG. 3I, each lateral opening 312 can be filled with a second sacrificial material. The second sacrificial material can be different from the first sacrificial material filled in contact hole 308. For example, each lateral opening 312 may be filled by depositing the second sacrificial material, such as polysilicon, into the opening using one or more thin film deposition processes, such as ALD, CVD, PVD, any other suitable processes, or any combination thereof. A portion of the second sacrificial material filled in lateral opening 312 which is below dielectric opening 311 can be removed to form a bottom opening 313, so that the remainder of the second sacrificial material filled in lateral opening 312 can form a sacrificial structure 314. For example, sacrificial structure 314 may have a ring shape surrounding bottom opening 313. Sacrificial structure 314 extends laterally from dielectric portion 207 into conductive portion 205 of stack structure 221 (e.g., as shown in FIG. 3L).

As illustrated in FIGS. 3J and 3K (FIG. 3J is a cross section along the AA direction of FIG. 3K, and FIG. 3K is a plan view of stack structure 221), with respect to each dielectric opening 311, a corresponding dielectric structure 218 may be formed by filling dielectric opening 311, as well as bottom opening 313 derived by removing the portion of the second sacrificial material filled below dielectric opening 311, with a dielectric material. For example, dielectric opening 311 and bottom opening 313 may be filled by depositing a dielectric material, such as silicon oxide, into the openings using one or more thin film deposition processes, such as ALD, CVD, PVD, any other suitable processes, or any combination thereof. The dielectric material used to form dielectric structure 218 may be different from the first sacrificial material (e.g., carbon) filled in contact hole 308 and the second sacrificial material (e.g., polysilicon) used to form sacrificial structure 314. Sacrificial structure 314 surrounds a bottom portion of a corresponding dielectric structure 218.

A cross section along the BB direction in second dielectric layer 225A of FIG. 3J is shown in FIG. 3L. As illustrated in FIG. 3L, contact hole 308 filled with the first sacrificial material extends through sacrificial structure 314 outside dielectric structure 218 (e.g., on a first side of dielectric structure 218). One or more first isolation holes 306A filled with the first sacrificial material may also extend through sacrificial structure 314 outside dielectric structure 218 (e.g., on a second side of dielectric structure 218 opposite to the first side of dielectric structure 218). Second isolation holes 306B filled with the first sacrificial material may extend into stack structure 221 outside sacrificial structure 314.

As illustrated in FIG. 3M, the first sacrificial material filled in isolation holes 306 can be removed. The first sacrificial material filled in slit holes 310 and contact holes 308 remains intact. For example, the first sacrificial material can be patterned using lithography and wet etching and/or dry etching to remove the part of the first sacrificial material filled in isolation holes 306, leaving the part of the first sacrificial material filled in slit holes 310 and contact holes 308 intact.

As illustrated in FIG. 3N, for each isolation hole 306, isolation recesses 320 can be formed in second dielectric layers 225 through isolation hole 306. Then, isolation recesses 320 and isolation hole 306 together may form an extended isolation hole. For example, parts of second dielectric layers 225 are removed by wet etching to form isolation recesses 320 through isolation hole 306, creating isolation recesses 320 interleaved between first dielectric layers 223. The wet etchant can include phosphoric acid for etching second dielectric layers 225 including silicon nitride. In some implementations, the etching rate and/or etching time are controlled to remove only parts of second dielectric layers 225 such that adjacent isolation holes 306 can be connected to one another through isolation recesses 320. That is, extended isolation holes formed by respective isolation holes 306 and isolation recesses 320 are connected to one another.

Because first isolation hole 306A (shown in FIG. 3L) is surrounded by the second sacrificial material of sacrificial structure 314 in second dielectric layer 225A, no isolation recess 320 is formed in second dielectric layer 225A for first isolation hole 306A. However, in other second dielectric layers 225, isolation recesses 320 are also formed through first isolation hole 306A for first isolation hole 306A. On the other hand, because second isolation hole 306B (shown in FIG. 3L) is not surrounded by the second sacrificial material of sacrificial structure 314 in second dielectric layer 225A, isolation recesses 320 are formed in second dielectric layer 225A for second isolation hole 306B, as well as in other second dielectric layers 225.

As illustrated in FIGS. 30 and 3P (FIG. 3P is a cross section along the BB direction of FIG. 3O), isolation structure 214 can be formed by forming isolation members in isolation holes 306. For example, isolation members can be formed in extended isolation holes corresponding to isolation holes 306, respectively. As illustrated in FIG. 3P, one or more first isolation members 234 may be formed in one or more first isolation holes 306A shown in FIG. 3L (e.g., in extended isolation holes corresponding to first isolation holes 306A); and second isolation members 236 may be formed in second isolation holes 306B shown in FIG. 3L (e.g., in extended isolation holes corresponding to second isolation holes 306B). In a cross-section of isolation structure 214 in second dielectric layer 225A shown in FIG. 3P, first isolation members 234 are separated from one another by the second sacrificial material of sacrificial structure 314, whereas second isolation members 236 are connected to one another to form an isolation wall. The isolation wall has two sidewalls, with each sidewall including a plurality of arc surfaces connected to one another.

To form each isolation member 234 or 236 in a respective extended isolation hole, an isolation spacer may be formed in the respective extended isolation hole. The isolation spacer can be formed by depositing a dielectric material (e.g., silicon oxide) into the respective extended isolation hole using one or more thin film deposition processes, such as ALD, CVD, PVD, any other suitable processes, or any combination thereof. In some implementations, another dielectric material (e.g., polysilicon) is deposited into the respective extended isolation hole after the isolation spacer as part of the isolation member. In the cross-section of isolation structure 214 in second dielectric layer 225A shown in FIG. 3P, isolation spacers of adjacent second isolation members 236 may be connected to one another, and isolation spacers of adjacent first isolation members 234 are separate from one another.

As illustrated in FIG. 3Q (FIG. 3Q is a cross section along the CC direction shown in FIG. 3S), the first sacrificial material filled in slit holes 310 can be removed. The first sacrificial material filled in contact holes 308 remains intact. For example, the first sacrificial material can be patterned using lithography and wet etching and/or dry etching to remove the part of the first sacrificial material filled in slit holes 310, leaving the part of the first sacrificial material filled in contact holes 308 intact.

As illustrated in FIGS. 3R and 3S (FIG. 3R is a cross section along the CC direction shown in FIG. 3S, and FIG. 3S is a cross section along the BB direction shown in FIG. 3O), slit recesses 324 can be formed in second dielectric layers 225 for each slit hole 310. Then, slit recesses 324 and slit hole 310 together may form an extended slit hole 326 shown in FIG. 3S. For example, parts of second dielectric layers 225 are removed by wet etching to form slit recesses 324 through slit hole 310, creating slit recesses 324 interleaved between first dielectric layers 223. The wet etchant can include phosphoric acid for etching second dielectric layers 225 including silicon nitride. In some implementations, the etching rate and/or etching time are controlled to remove only parts of second dielectric layers 225 such that adjacent slit holes 310 are connected to one another through slit recesses 324. That is, adjacent extended slit holes 326 formed by respective slit holes 310 and slit recesses 324 are connected to one another.

As illustrated in FIGS. 3T and 3U (FIG. 3T is a cross section along the CC direction, and FIG. 3U is a cross section along the BB direction), parts of second dielectric layers 225 in core array region 201 and conductive portion 205 of word line pick-up region 203 are removed by wet etching to form lateral recesses 328, leaving the parts of second dielectric layers 225 in dielectric portion 207 of word line pick-up region 203 intact. In some implementations, the parts of second dielectric layers 225 are wet etched by applying a wet etchant through extended slit holes 326, creating lateral recesses 328 interleaved between first dielectric layers 223 in core array region 201 and conductive portion 205 of word line pick-up region 203. The wet etchant can include phosphoric acid for etching second dielectric layers 225 including silicon nitride. In some implementations, the etching rate and/or etching time are controlled to remove the parts of second dielectric layers 225 in core array region 201 and conductive portion 205 of word line pick-up region 203. Due to the existence of isolation structure 214 and sacrificial structure 314, which are resistant to the etchant for removing second dielectric layers 225, the parts of second dielectric layers 225 in dielectric portion 207 remain intact.

For example, as illustrated in FIG. 3U, a part of second dielectric layer 225A in dielectric portion 207 of word line pick-up region 203 remains intact, whereas a part of second dielectric layer 225A in core array region 201 and conductive portion 205 of word line pick-up region 203 is removed. In FIG. 3U, locations of extended slit holes 326 are illustrated using dashed lines.

As illustrated in FIGS. 3V and 3W (FIG. 3V is a cross section along the CC direction, and FIG. 3W is a cross section along the BB direction), sacrificial structure 314 is also removed to expose a sacrificial opening 330. For example, since a part of lateral opening 312 (e.g., bottom opening 313 shown in FIG. 3I) is already occupied by dielectric structure 218, sacrificial opening 330 is a remaining portion of lateral opening 312, which is not occupied by dielectric structure 218. Sacrificial opening 330 may have a ring shape. In some implementations, sacrificial structure 314 is etched away from a corresponding lateral recess 328 in the same layer as sacrificial structure 314, for example, using potassium hydroxide (KOH) for etching sacrificial structure 314 having polysilicon.

As illustrated in FIGS. 3X and 3Y (FIG. 3X is a cross section along the CC direction, and FIG. 3Y is a cross section along the BB direction), sacrificial opening 330 may be filled with a conductive material to form conductive structure 216 through a corresponding lateral recess 328 in the same layer as sacrificial opening 330. Meanwhile, lateral recesses 328 may also be filled with the conductive material to form conductive layers 227 in core array region 201 and conductive portion 205 of word line pick-up region 203 through slit holes 310 (or extended slit holes 326). In some implementations, high-k gate dielectric layers are deposited into lateral recesses 328 and sacrificial opening 330 prior to filling with the conductive material, such that conductive layers 227 and conductive structure 216 are deposited on and surrounded by high-k gate dielectric layers. A portion of contact hole 308 filled with the first sacrificial material in the same layer as conductive structure 216 (e.g., a portion 402 shown in FIG. 4C) is also surrounded by a high-k gate dielectric layer. Conductive layers 227 and conductive structure 216 can be deposited using one or more thin film deposition processes, such as ALD, CVD, PVD, any other suitable processes, or any combination thereof.

As illustrated in FIG. 3Y, only the part of second dielectric layer 225A in dielectric portion 207 of word line pick-up region 203 remains intact. The part of second dielectric layer 225A in core array region 201 and conductive portion 205 of word line pick-up region 203 is replaced by conductive layer 227A.

As illustrated in FIGS. 4A and 4B (FIG. 4A is a cross section along the CC direction, and FIG. 4B is a cross section along the BB direction), slit structure 208 including first slit members 230 and second slit members 232 can be formed. First slit members 230 may be formed in a first subset of slit holes 310 (or extended slit holes 326) on a side of dielectric structure 218, and second slit members 232 may be formed in a second subset of slit holes 310 (or extended slit holes 326) on another side of dielectric structure 218. In a cross-section of slit structure 208 in a lateral plane shown in FIG. 4B, first slit members 230 are connected to one another to form a first slit wall, and second slit members 232 are also connected to one another to form a second slit wall. Each of the first and second slit walls has two sidewalls, with each sidewall including a plurality of arc surfaces connected to one another.

To form each slit member 230 or 232 in a respective extended slit hole, a slit spacer may be first formed in the respective extended slit hole. The slit spacer can be formed by depositing a dielectric material (e.g., silicon oxide) into the respective extended slit hole using one or more thin film deposition processes, such as ALD, CVD, PVD, any other suitable processes, or any combination thereof. In some implementations, another dielectric material (e.g., polysilicon) is deposited into the respective extended slit hole after the slit spacer as part of the slit member. Alternatively, a conductive material (e.g., as a source contact) is deposited into the respective extended slit hole after the slit spacer as part of the slit member. Slit spacers of adjacent first slit members 230 may be connected to one another to form the first slit wall. Slit spacers of adjacent second slit members 232 may also be connected to one another to form the second slit wall.

As illustrated in FIGS. 4C and 4D (FIG. 4C is a cross section along the CC direction, and FIG. 4D is a cross section along the BB direction), the first sacrificial material filled in contact holes 308 can be removed. The first sacrificial material filled in contact holes 308 can be patterned using lithography and wet etching and/or dry etching to remove the part of the first sacrificial material filled in contact holes 308. In some implementations in which high-k gate dielectric layers are formed surrounding conductive layer 227 and conductive structure 216, once the first sacrificial material is removed from contact hole 308, the corresponding high-k gate dielectric layer which surrounds portion 402 of contact hole 308 at the same level as conductive structure 216 is exposed. The exposed part of the corresponding high-k gate dielectric layer can then be etched, for example, using wet etching, to expose the corresponding conductive structure 216 at the same level.

As illustrated in FIGS. 4E and 4F (FIG. 4E is a cross section along the CC direction, and FIG. 4F is a cross section along the BB direction), contact structures 220 may be formed in contact holes 308 by depositing a conductive material to fill the respective contact holes 308. The conductive material can be deposited using one or more thin film deposition processes, such as ALD, CVD, PVD, any other suitable processes, or any combination thereof. Contact structures 220 formed thereof extend through corresponding conductive structures 216, respectively, and are connected to corresponding conductive structures 216, respectively.

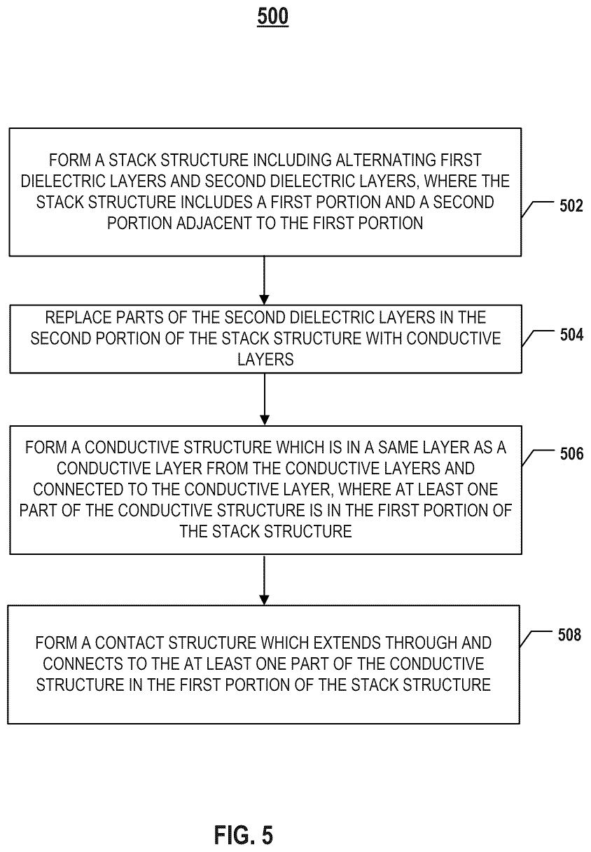

FIG. 5 is a flowchart of a method 500 for forming a 3D memory device having contact structures, according to some aspects of the present disclosure. The 3D memory device can be 3D memory device 200 or any other memory device disclosed herein. It is understood that the operations shown in method 500 are not exhaustive and that other operations can be performed as well before, after, or between any of the illustrated operations. Further, some of the operations may be performed simultaneously, or in a different order than shown in FIG. 5.

Referring to FIG. 5, method 500 starts at operation 502, in which a stack structure including alternating first dielectric layers and second dielectric layers can be formed. The stack structure includes a first portion and a second portion adjacent to the first portion. For example, stack structure 221 can be formed by performing operations like those described above with reference to FIGS. 3A and 3B. The first portion of stack structure 221 may include dielectric portion 207 of word line pick-up region 203. The second portion of stack structure 221 may include (1) conductive portion 205 of word line pick-up region 203 and (2) core array region 201.

Method 500 proceeds to operation 504, as illustrated in FIG. 5, in which parts of the second dielectric layers in the second portion of the stack structure can be replaced with conductive layers. For example, parts of second dielectric layers 225 in the second portion of stack structure 221 can be replaced with conductive layers 227 by performing operations like those described above with reference to FIGS. 3Q-3Y, and the similar description will not be repeated herein.

Method 500 proceeds to operation 506, as illustrated in FIG. 5, in which a conductive structure may be formed. The conductive structure is in a same layer as a conductive layer from the conductive layers and connected to the conductive layer. At least one part of the conductive structure is in the first portion of the stack structure. For example, conductive structure 216 can be formed by performing operations like those described above with reference to FIGS. 3Q-3Y, and the similar description will not be repeated herein.

Method 500 proceeds to operation 508, as illustrated in FIG. 5, in which a contact structure is formed. The contact structure extends through and connects to the at least one part of the conductive structure in the first portion of the stack structure. For example, contact structure 220 can be formed by performing operations like those described above with reference to FIGS. 4C-4F, and the similar description will not be repeated herein.

In some implementations, method 500 may further include forming an isolation structure extending through the stack structure. The isolation structure is located between the first portion and the second portion of the stack structure to isolate the first portion from the second portion. For example, with reference to FIGS. 3M-3P, isolation structure 214 extending through stack structure 221 may be formed. Isolation structure 214 may be located between dielectric portion 207 and conductive portion 205 of word line pick-up region 203 to isolate dielectric portion 207 from (1) conductive portion 205 of word line pick-up region 203 and (2) core array region 201.

In some implementations, the isolation structure surrounds the first portion of the stack structure, and the conductive structure extends through the isolation structure to connect to the conductive layer in the second portion of the stack structure. For example, with reference to FIG. 4F, isolation structure 214 (including first isolation members 234 and second isolation members 236) may surround dielectric portion 207 of word line pick-up region 203. Conductive structure 216 extends through isolation structure 214 to connect to conductive layer 227A in conductive portion 205 of word line pick-up region 203 and core array region 201.

In some implementations, as shown in FIG. 4F, isolation structure 214 may include (1) one or more first isolation members 234 extending into stack structure 221 through conductive structure 216 and (2) second isolation members 236 extending into stack structure 221 outside conductive structure 216. In a cross-section of isolation structure 214 in a lateral plane shown in FIG. 4F, one or more first isolation members 234 are surrounded by and separated by conductive structure 216, and second isolation members 236 are connected to one another to isolate conductive layer 227A from a remainder part of second dielectric layer 225A in dielectric portion 207 of word line pick-up region 203. The remainder part of second dielectric layer 225A is in the same layer as conductive layer 227A.

In some implementations, method 500 may further include forming a dielectric structure extending into the first portion of the stack structure in a same direction as the contact structure. The dielectric structure extends through the at least one part of the conductive structure in the first portion of the stack structure, and a bottom portion of the dielectric structure is surrounded by the at least one part of the conductive structure. For example, dielectric structure 218 may be formed by performing operations like those described above with reference to FIGS. 3G-3L. As shown in FIG. 4E, dielectric structure 218 extends through a part of conductive structure 216 in the first portion of stack structure 221 (e.g., dielectric portion 207 of word line pick-up region 203), and a bottom portion of dielectric structure 218 is surrounded by the part of conductive structure 216. Dielectric structure 218 may have a pillar shape.

In some implementations, to form the contact structure, operation 508 may include forming the contact structure extending through the at least one part of the conductive structure outside the dielectric structure. For example, as shown in FIG. 4F, contact structure 220 corresponding to conductive structure 216 extends through the part of conductive structure 216 in dielectric portion 207 of word line pick-up region 203 outside dielectric structure 218.

In some implementations, method 500 may further include forming a channel structure extending through the second portion of the stack structure in a same direction as the contact structure, and forming a slit structure extending through the second portion of the stack structure in the same direction as the contact structure. For example, channel structure 110 may be formed by performing operations like those described above with reference to FIGS. 3E-3F. Slit structure 208 may be formed by performing operations like those described above with reference to FIGS. 4A-4B.

In some implementations, method 500 may further include forming a channel hole and a plurality of slit holes in the second portion of the stack structure, a plurality of isolation holes between the first portion and the second portion of the stack structure, and a contact hole in the first portion of the stack structure. Method 500 may also include filling the channel hole, the plurality of slit holes, the plurality of isolation holes, and the contact hole with a first sacrificial material. For example, channel hole 302, slit hole 310, isolation hole 306, and contact hole 308 may be formed and filled with the first sacrificial material by performing operations like those described above with reference to FIGS. 3A-3D.

In some implementations, to form the channel structure, method 500 may further include removing the first sacrificial material filled in the channel hole and forming the channel structure in the channel hole. For example, operations like those described above with reference to FIGS. 3E-3F can be performed to form channel structure 210.

In some implementations, to form the conductive structure, operation 506 may further include: forming a dielectric opening in the first portion of the stack structure to expose a second dielectric layer under the dielectric opening, where the second dielectric layer is in the same layer as the conductive layer; removing a portion of the second dielectric layer through the dielectric opening to form a lateral opening in the second dielectric layer, where the lateral opening extends laterally from the first portion into the second portion of the stack structure; filling the lateral opening with a second sacrificial material; and forming a sacrificial structure including the second sacrificial material filled in the lateral opening by removing a portion of the second sacrificial material filled below the dielectric opening, where the sacrificial structure also extends laterally from the first portion into the second portion of the stack structure. For example, operations like those described above with reference to FIGS. 3G-31 can be performed to form sacrificial structure 314.

In some implementations, to form the dielectric structure, method 500 further includes filling the dielectric opening, as well as an opening derived by removing the portion of the second sacrificial material filled below the dielectric opening, with a dielectric material to form the dielectric structure. The sacrificial structure surrounds the bottom portion of the dielectric structure. For example, operations like those described above with reference to FIGS. 3J-3L can be performed to form dielectric structure 218. Sacrificial structure 314 surrounds the bottom portion of dielectric structure 218.

In some implementations, to form the isolation structure, method 500 may further include removing the first sacrificial material filled in the plurality of isolation holes, and forming a plurality of isolation members in the plurality of isolation holes. In some implementations, the plurality of isolation holes may include one or more first isolation holes extending through the conductive structure and second isolation holes extending outside the conductive structure. Forming the plurality of isolation members in the plurality of isolation holes may include forming one or more first isolation members in the one or more first isolation holes, and forming second isolation members in the second isolation holes. In some implementations, forming the second isolation members in the second isolation holes may include: forming extended isolation holes by, for each second isolation hole, forming isolation recesses in the second dielectric layers through the second isolation hole, where the isolation recesses and the second isolation hole form a corresponding extended isolation hole; and forming the second isolation members in the extended isolation holes. In a cross-section of the isolation structure in a lateral plane perpendicular to an extending direction of the contact structure, the second isolation members are connected to one another to form an isolation wall, and a sidewall of the isolation wall may include a plurality of arc surfaces connected to one another. For example, operations like those described above with reference to FIGS. 3M-3P can be performed to form isolation structure 214 including first isolation members 234 and second isolation members 236.

In some implementations, to replace the parts of the second dielectric layers in the second portion of the stack structure with the conductive layers, operation 504 may further include: removing the first sacrificial material filled in the plurality of slit holes; and removing the parts of the second dielectric layers in the second portion of the stack structure through the plurality of slit holes to form a plurality of lateral recesses. For example, operations like those described above with reference to FIGS. 3Q-3U can be performed to form lateral recesses 328.

In some implementations, to form the conductive structure, operation 506 may further include: removing the sacrificial structure through a lateral recess to form a sacrificial opening, where the lateral recess is one of the plurality of lateral recesses in the same layer as the conductive layer; and filling the sacrificial opening with a conductive material to form the conductive structure. For example, operations like those described above with reference to FIGS. 3V-3Y can be performed to form conductive structure 216.

In some implementations, to replace the parts of the second dielectric layers in the second portion of the stack structure with the conductive layers, operation 504 may further include filling the plurality of lateral recesses with the conductive material to form the conductive layers. For example, operations like those described above with reference to FIGS. 3X-3Y can be performed to form conductive layers 227.

In some implementations, to form the slit structure, method 500 may further include: forming a plurality of first slit members in a first subset of the plurality of slit holes; and forming a plurality of second slit members in a second subset of the plurality of slit holes. In a cross-section of the slit structure in a lateral plane perpendicular to an extending direction of the contact structure, the plurality of first slit members are connected to one another, and the plurality of second slit members are also connected to one another. For example, operations like those described above with reference to FIGS. 4A-4B can be performed to form slit structure 208 including first slit members 230 and second slit members 232.

In some implementations, to form the contact structure, operation 508 may further include: removing the first sacrificial material filled in the contact hole; and forming the contact structure in the contact hole. For example, operations like those described above with reference to FIGS. 4C-4F can be performed to form contact structure 220.

In some implementations, the stack structure may include: a first stack segment including a first subset of the alternating first and second dielectric layers over the semiconductor layer; and a second stack segment including a second subset of the alternating first and second dielectric layers. Forming the channel hole, the plurality of slit holes, the plurality of isolation holes, and the contact hole may include: forming a first channel opening, a plurality of first isolation openings, a plurality of first slit openings, and a first contact opening in the first stack segment; forming a second channel opening, a plurality of second isolation openings, a plurality of second slit openings, and a second contact opening in the second stack segment; and combining the first stack segment with the second stack segment to form the stack structure in which the channel hole, the plurality of isolation holes, the plurality of slit holes, and the contact hole are formed. The channel hole may include the first and second channel openings. The plurality of isolation holes may include the plurality of first isolation openings and the plurality of second isolation openings, respectively. The plurality of slit holes may include the plurality of first slit openings and the plurality of second slit openings, respectively. The contact hole may include the first and second contact openings. For example, operations like those described above with reference to FIGS. 3A-3B can be performed to form channel hole 302, slit hole 310, isolation hole 306, and contact hole 308.

The channel structure may include a first channel segment formed in the first channel opening and a second channel segment formed in the second channel opening. The isolation structure may include first isolation segments formed in the plurality of first isolation openings, respectively, and second isolation segments formed in the plurality of second isolation openings, respectively. The contact structure may include a first contact segment formed in the first contact opening and a second contact segment formed in the second contact opening. The slit structure may include first slit segments formed in the plurality of first slit openings, respectively, and second slit segments formed in the plurality of second slit openings, respectively.

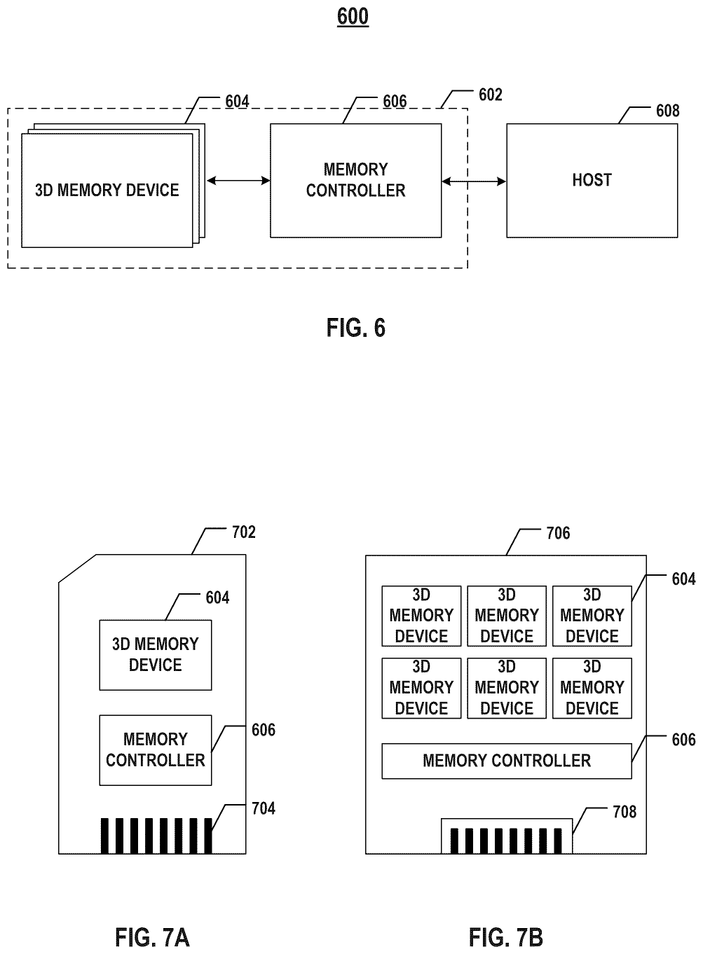

FIG. 6 illustrates a block diagram of an exemplary system 600 having a 3D memory device, according to some aspects of the present disclosure. System 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, system 600 can include a host 608 and a memory system 602 having one or more 3D memory devices 604 and a memory controller 606. Host 608 can be a processor of an electronic device, such as a central processing unit (CPU), or a system-on-chip (SoC), such as an application processor (AP). Host 608 can be configured to send or receive data to or from 3D memory devices 604.

3D memory device 604 can be any 3D memory device disclosed herein, such as 3D memory device 200 depicted in FIGS. 2A-2D. In some implementations, each 3D memory device 604 includes a NAND Flash memory. Consistent with the scope of the present disclosure, conductive structures 216 and contact structures 220 can be used to replace the staircase structures and word line contacts to achieve word line pick-up/fan-out functions, thereby reducing the manufacturing cost and simplifying the fabrication process.

Memory controller 606 (a.k.a., a controller circuit) is coupled to 3D memory device 604 and host 608 and is configured to control 3D memory device 604, according to some implementations. For example, memory controller 606 may be configured to operate the plurality of channel structures via the word lines. Memory controller 606 can manage the data stored in 3D memory device 604 and communicate with host 608. In some implementations, memory controller 606 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed for operating in a high duty-cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604. Memory controller 606 can communicate with an external device (e.g., host 608) according to a particular communication protocol. For example, memory controller 606 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 7A, memory controller 606 and a single 3D memory device 604 may be integrated into a memory card 702. Memory card 702 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 702 can further include a memory card connector 704 electrically coupling memory card 702 with a host (e.g., host 608 in FIG. 6). In another example as shown in FIG. 7B, memory controller 606 and multiple 3D memory devices 604 may be integrated into an SSD 706. SSD 706 can further include an SSD connector 708 electrically coupling SSD 706 with a host (e.g., host 608 in FIG. 6). In some implementations, the storage capacity and/or the operation speed of SSD 706 is greater than those of memory card 702.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A memory device, comprising:
a stack structure comprising alternating first layers and first dielectric layers, wherein the first layers in a first portion of the stack structure comprise second dielectric layers, and the first layers in a second portion adjacent to the first portion of the stack structure comprise conductive layers;
a conductive structure in a same layer as a conductive layer from the conductive layers and connected to the conductive layer, wherein at least one part of the conductive structure is in the first portion of the stack structure; and
a contact structure extending through and connected to the at least one part of the conductive structure in the first portion of the stack structure.

2. The memory device of claim 1, further comprising:
an isolation structure extending through the stack structure,
wherein the isolation structure is located between the first portion and the second portion of the stack structure to isolate the first portion from the second portion.

3. The memory device of claim 2, wherein the isolation structure surrounds the first portion of the stack structure, and the conductive structure extends through the isolation structure to connect to the conductive layer in the second portion of the stack structure.

4. The memory device of claim 2, wherein the isolation structure comprises:
one or more first isolation members extending into the stack structure through the conductive structure; and
second isolation members extending into the stack structure outside the conductive structure,
wherein in a cross-section of the isolation structure in a lateral plane perpendicular to an extending direction of the contact structure, the one or more first isolation members are surrounded by and separated by the conductive structure, and the second isolation members are connected to one another to isolate the conductive layer from one of the second dielectric layers in the same layer as the conductive layer.

5. The memory device of claim 4, wherein in the cross-section of the isolation structure in the lateral plane, the second isolation members are connected to one another to form an isolation wall, and a sidewall of the isolation wall comprises a plurality of arc surfaces connected to one another.

6. The memory device of claim 2, further comprising:
a dielectric structure extending into the first portion of the stack structure in a same direction as the contact structure,
wherein the dielectric structure extends through the at least one part of the conductive structure, and a bottom portion of the dielectric structure is surrounded by the at least one part of the conductive structure.

7. The memory device of claim 6, wherein the contact structure extends through the at least one part of the conductive structure outside the dielectric structure.

8. The memory device of claim 6, further comprising:
a channel structure extending through the second portion of the stack structure in a same direction as the contact structure; and
a slit structure extending through the second portion of the stack structure in the same direction as the contact structure.

9. The memory device of claim 8, wherein:
the channel structure comprises a plurality of channel segments;
the isolation structure comprises isolation members each of which comprises a plurality of isolation segments corresponding to the plurality of channel segments, respectively;
the contact structure comprises a plurality of contact segments corresponding to the plurality of channel segments, respectively; and
the slit structure comprises slit members each of which comprises a plurality of slit segments corresponding to the plurality of channel segments, respectively.

10. The memory device of claim 9, wherein:
the plurality of channel segments comprise a first channel segment and a second channel segment on the first channel segment;
a first end of the first channel segment is away from the second channel segment, a second end of the first channel segment is connected to a first end of the second channel segment, and a second end of the second channel segment is away from the first channel segment; and
in a lateral direction perpendicular to an extending direction of the contact structure, a size of the first end of the first channel segment is smaller than a size of the second end of the first channel segment, and a size of the first end of the second channel segment is smaller than the size of the second end of the first channel segment and a size of the second end of the second channel segment.

11. The memory device of claim 8, wherein the slit structure comprises:
a plurality of first slit members and a plurality of second slit members extending through the second portion of the stack structure, wherein in a cross-section of the slit structure in a lateral plane perpendicular to an extending direction of the contact structure, the plurality of first slit members are connected to one another, and the plurality of second slit members are also connected to one another.

12. The memory device of claim 11, wherein:
the dielectric structure is located between the plurality of first slit members and the plurality of second slit members;
a first distance between the dielectric structure and the plurality of first slit members is smaller than a second distance between the dielectric structure and the plurality of second slit members; and
the contact structure is located between the dielectric structure and the plurality of second slit members.

13. A method for forming a memory device, comprising:
forming a stack structure comprising alternating first dielectric layers and second dielectric layers, wherein the stack structure comprises a first portion and a second portion adjacent to the first portion;
replacing parts of the second dielectric layers in the second portion of the stack structure with conductive layers;
forming a conductive structure that is in a same layer as a conductive layer from the conductive layers and connected to the conductive layer, wherein at least one part of the conductive structure is in the first portion of the stack structure; and
forming a contact structure that extends through and connects to the at least one part of the conductive structure in the first portion of the stack structure.

14. The method of claim 13, further comprising:
forming an isolation structure extending through the stack structure, wherein the isolation structure is located between the first portion and the second portion of the stack structure to isolate the first portion from the second portion,
wherein the isolation structure surrounds the first portion of the stack structure, and the conductive structure extends through the isolation structure to connect to the conductive layer in the second portion of the stack structure.

15. The method of claim 13, further comprising:
forming a dielectric structure extending into the first portion of the stack structure in a same direction as the contact structure,
wherein the dielectric structure extends through the at least one part of the conductive structure, and a bottom portion of the dielectric structure is surrounded by the at least one part of the conductive structure.

16. The method of claim 15, wherein forming the contact structure comprises:
forming the contact structure extending through the at least one part of the conductive structure outside the dielectric structure.

17. The method of claim 15, further comprising:
forming a channel structure extending through the second portion of the stack structure in a same direction as the contact structure; and
forming a slit structure extending through the second portion of the stack structure in the same direction as the contact structure.

18. The method of claim 15, wherein forming the conductive structure comprises:
forming a dielectric opening in the first portion of the stack structure to expose a second dielectric layer under the dielectric opening, wherein the second dielectric layer is in the same layer as the conductive layer;
removing a portion of the second dielectric layer through the dielectric opening to form a lateral opening in the second dielectric layer, wherein the lateral opening extends laterally from the first portion into the second portion of the stack structure;
filling the lateral opening with a sacrificial material; and
forming a sacrificial structure comprising the sacrificial material filled in the lateral opening by removing a portion of the sacrificial material filled below the dielectric opening, wherein the sacrificial structure also extends laterally from the first portion into the second portion of the stack structure.

19. The method of claim 18, wherein forming the dielectric structure comprises:
filling the dielectric opening, as well as an opening derived by removing the portion of the sacrificial material filled below the dielectric opening, with a dielectric material to form the dielectric structure, wherein the sacrificial structure surrounds the bottom portion of the dielectric structure.

20. A memory device, comprising:
a stack structure comprising alternating first layers and first dielectric layers, wherein the first layers in a first portion of the stack structure comprise second dielectric layers, and the first layers in a second portion adjacent to the first portion of the stack structure comprise conductive layers;
a conductive structure in a same layer as a conductive layer from the conductive layers and connected to the conductive layer, wherein at least one part of the conductive structure is in the first portion of the stack structure; and
an isolation structure extending through the stack structure and surrounding the first portion of the stack structure.
